(19) United States
(12) Patent Application Publication
(10) Pub. No.: US 2026/0173341 A1
(43) Pub. Date: Jun. 18, 2026

(54) INTEGRATED CIRCUIT INCLUDING BIT CELLS

(71) Applicant: Samsung Electronics Co., Ltd., Suwon-si (KR)

(72) Inventors: Chanho LEE, Suwon-si (KR); Suk YOUN, Suwon-si (KR)

(21) Appl. No.: 19/417,029

(22) Filed: Dec. 11, 2025

(30) Foreign Application Priority Data
Dec. 13, 2024 (KR) 10-2024-0185703
Apr. 23, 2025 (KR) 10-2025-0052937

(51) Int. Cl. H10B 10/00

(52) U.S. Cl. CPC H10B 10/12

(57) ABSTRACT

An integrated circuit including a plurality of bit cells. A first bit cell among the plurality of bit cells includes a plurality of first transistors in a first active region extending in a first direction, a plurality of second transistors in a second active region that is spaced apart from the first active region in a second direction intersecting the first direction, and that extends in the first direction, and a plurality of third transistors that are disposed in a third active region between the first active region and the second active region. The third active region extends in the first direction. A number of the plurality of third transistors is smaller than a number of the plurality of first transistors.

### CROSS-REFERENCE TO RELATED APPLICATIONS

This application claims the benefit of the earlier filing dates and the right of priority under 35 USC § 119 to Korean Patent Application No. 10-2024-0185703, filed on Dec. 13, 2024, and Korean Patent Application No. 10-2025-0052937, filed on Apr. 23, 2025, in the Korean Intellectual Property Office, the disclosures of which are incorporated herein in their entireties by reference.

### TECHNICAL FIELD

This application relates to an integrated circuit, and more specifically, relate to an integrated circuit including bit cells.

### BACKGROUND

With the development of semiconductor processes and the demand for higher integration, the size of bit cells included in integrated circuits may become smaller, and the match characteristics between transistors included in the bit cells are emerging as a more important factor. For example, depending on the arrangement of transistors or the distance between each transistor and the well region, there may be a mismatch (or deviation) in the electrical characteristics between transistors, and such mismatches can degrade the performance of bit cells and integrated circuits including bit cells.

### SUMMARY

An aspect provides an integrated circuit including bit cells with improved match characteristics.

According to an aspect, there is provided an integrated circuit including a plurality of bit cells, and a first bit cell among the plurality of bit cells includes a plurality of first transistors in a first active region extending in a first direction, a plurality of second transistors in a second active region that is spaced apart from the first active region in a second direction intersecting the first direction, and that extends in the first direction, and a plurality of third transistors in a third active region between the first active region and the second active region. The third active region extends in the first direction. A number of the plurality of third transistors is smaller than a number of the plurality of first transistors.

According to an aspect, there is provided an integrated circuit including a plurality of bit cells, and a first bit cell among the plurality of bit cells includes a first pass transistor and a second pass transistor that are spaced apart from each other in a first direction, and that are connected to a first bit line and a first complementary bit line respectively, a first pull-down transistor and a second pull-down transistor between the first pass transistor and the second pass transistor, and a first pull-up transistor and a second pull-up transistor spaced apart from the first pull-down transistor and the second pull-down transistor respectively, in a second direction that is intersecting the first direction.

According to an aspect, there is provided an integrated circuit including a plurality of bit cells, and a first bit cell among the plurality of bit cells includes a first pattern extending in a first direction on a first interconnection layer, and configured to apply a positive supply voltage, a second pattern extending in a second direction that is intersecting the first direction on a second interconnection layer, and configured to apply a negative supply voltage, an inverter pair that is configured to be driven by the positive supply voltage and the negative supply voltage, and cross-coupled between a first data node and a second data node, a first pass transistor connected to the first data node, and a second pass transistor connected to the second data node, and spaced apart from the first pass transistor in the first direction. A first inverter of the inverter pair includes a first pull-down transistor, a first pull-up transistor and a second pull-down transistor that are in the second direction, and the first pull-down transistor is between the first pass transistor and the second pass transistor.

According to example embodiments, it is possible to provide an integrated circuit including bit cells with improved match characteristics.

According to example embodiments, it is possible to provide a layout in which transistors of a bit cell are arranged symmetrically, and accordingly, the characteristics deviation between transistors included in a bit cell may be reduced.

According to example embodiments, it is possible to provide a word line with extended width, and the resistance of the word line may be reduced. According to example embodiments, it is possible to provide a gate contact shared with adjacent bit cells, and the capacitance of the word line may be reduced. Due to the reduced resistance and capacitance of the word line, bit cells that operate at high speed may be provided.

According to example embodiments, it is possible for bit lines of the same port to be placed adjacently, and the interference from bit lines of other ports may be reduced. According to example embodiments, it is possible to place power lines between word lines, and the interference between word lines may be reduced.

The effects achievable by the present disclosure are not limited to the effect mentioned above, and other effects not mentioned will be clearly understood by those of ordinary skill in the art to which the present disclosure pertains from the following description. In other words, unintended effects resulting from practicing the example embodiments of the present disclosure may also be derived from the example embodiments of the present disclosure by a person skilled in the art.

### BRIEF DESCRIPTION OF THE FIGURES

These and/or other aspects, features, and advantages of the disclosure will become apparent and more readily appreciated from the following description of example implementations, taken in conjunction with the accompanying drawings.

FIG. 1 is a block diagram illustrating an integrated circuit according to some example implementations.

FIG. 2 is a circuit diagram illustrating a bit cell according to some example implementations.

FIG. 3A to FIG. 3D are drawings illustrating transistors according to some example implementations.

FIG. 4A and FIG. 4B are plan views illustrating a bit cell according to some example implementations.

FIG. 5 to FIG. 9 are plan views illustrating the layout of bit cells according to some example implementations.

FIG. 10 to FIG. 12 are plan views illustrating the layout of bit cells according to some example implementations.

FIG. 13 is a circuit diagram illustrating a bit cell according to some example implementations.

FIG. 14 to FIG. 18 are plan views illustrating the layout of bit cells according to some example implementations.

FIG. 19 is a circuit diagram illustrating a bit cell according to some example implementations.

FIG. 20 and FIG. 21 are plan views illustrating the layout of a bit cell according to some example implementations.

FIG. 22 is a block diagram illustrating a system on chip (SoC) according to some example implementations.

### DETAILED DESCRIPTION

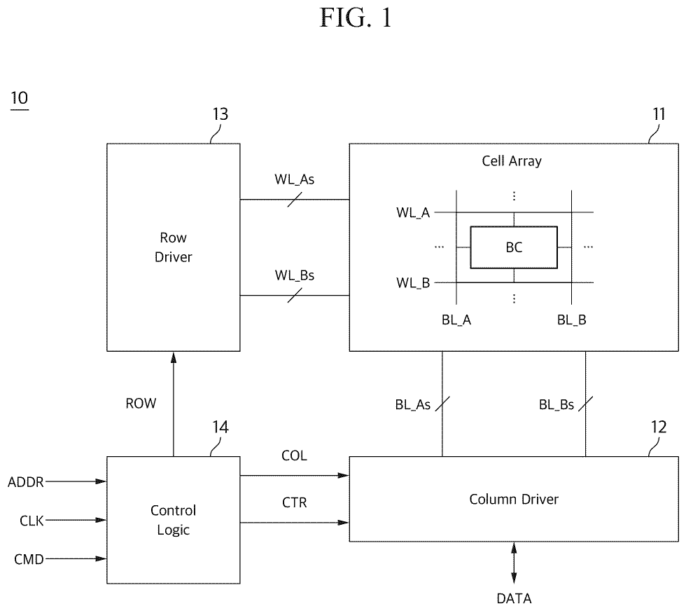

FIG. 1 is a block diagram illustrating an integrated circuit 10 according to some example implementations. FIG. 1 is intended to specifically illustrate one of various example implementations of the present disclosure. For example, the integrated circuit 10 may be implemented as a memory device. The integrated circuit 10 may transmit and receive a command CMD, an address ADDR, a clock signal CLK, and data DATA. For example, the integrated circuit 10 may receive the command CMD, the address ADDR and the data DATA instructing to write, and the data DATA may be stored in the area of a cell array 11 corresponding to the address ADDR. Further, the integrated circuit 10 may receive the command CMD and the address ADDR that instructs a read, and read the data DATA stored in the area of the cell array 11 corresponding to the address ADDR and output the data DATA to the outside.

Referring to FIG. 1, the integrated circuit 10 may include the cell array 11, a column driver 12, a row driver 13 and control logic 14. The cell array 11 may include a plurality of bit cells. The plurality of bit cells may be spaced apart from each other at regular intervals. In some example implementations, each of the plurality of bit cells may be electrically connected to at least one of a plurality of word lines WL_As and WL_Bs, and may be electrically connected to at least one of a plurality of bit line pairs BL_As and BL_Bs. Each of the plurality of bit line pairs may correspond to one port and may include a bit line and a complementary bit line.

In some example implementations, one bit line BC among a plurality of bit cells may be a memory cell. For example, the memory cells may be volatile memory cells of static random access memory (SRAM) and dynamic RAM (DRAM), or may be non-volatile memory cells such as flash memory and resistive RAM (ReRAM). In some example implementations, the description for the bit line BC may be equally applied to other bit cells.

In some example implementations, the bit line BC may be accessed independently through multiple ports. The plurality of word lines WL_As and WL_Bs and the plurality of bit line pairs BL_As and BL_Bs may be distinguished depending on the port. The bit line BC may be connected to the corresponding word line and bit line pair for each port. For example, the plurality of word lines WL_As and WL_Bs may include the word lines WL_As corresponding to a first port (for example, a port A) and the word lines WL_Bs corresponding to a second port (for example, a port B), and the plurality of bit line pairs BL_As and BL_Bs may include the bit line pairs BL_As corresponding to the first port (for example, the port A) and the bit line pairs BL_Bs corresponding to the second port (for example, the port B). As illustrated in FIG. 1, the bit line BC may be connected to a first word line WL_A and a first bit line pair BL_A corresponding to the first port and may connected to a second word line WL_B and a second bit line pair BL_B corresponding to the second port. Here, the bit line BC is a dual-port cell (hereinafter referred to as “DP-cell”) or two-port cell (hereinafter referred to as “TP-cell”). For example, the DP-cell may selectively perform either a write operation or a read operation through the first port, and selectively perform either a write operation or a read operation through the second port. In some example implementations, the TP-cell may only perform write operations through the first port, and only perform read operations through the second port. In another example embodiment, the TP-cell may selectively perform either a write operation or a read operation through the first port, and only perform read operations through the second port. The example implementations in the present disclosure will be described primarily with reference to a dual-port SRAM cell (hereinafter referred to as a “DP-SRAM cell”) or a two-port SRAM cell (hereinafter referred to as a “TP-SRAM cell”), but the example implementations are not limited thereto.

The row driver 13 may be connected to the cell array 11 via the plurality of word lines WL_As and WL_Bs. The row driver 13 may select and activate at least one word line among the plurality of word lines WL_As and WL_Bs based on a row address ROW. Accordingly, the bit cell connected to an activated word line may be selected from a plurality of bit cells.

The column driver 12 may be connected to the cell array 11 through the plurality of bit line pairs BL_As and BL_Bs. The column driver 12 may perform a read operation or a write operation based on a control signal CTR. The column driver 12 may select one bit line pair among the plurality of bit line pairs BL_As and BL_Bs based on a column address COL, and perform a read operation or a write operation through a selected bit line pair. According to some example implementations, the column driver 12 may include a read circuit that performs a read operation and a write circuit that performs a write operation. In the read operation, the column driver 12 may identify the value stored in the bit cell connected to the activated word line by sensing the current and/or voltage received across the selected bit line pair, and then may output the data DATA based on the identified value. In the write operation, the column driver 12 may write a value to a bit cell connected to an activated word line by applying current and/or voltage through a selected bit line pair based on the data DATA. The column driver 12 may include a bit line pre-charge circuit that pre-charges the plurality of bit line pairs BL_As and BL_Bs.

The control logic 14 may receive the command CMD, the address ADDR and the clock signal CLK from external devices, and generate the row address ROW, the column address COL and the control signal CTR. For example, the external devices may be a central processing unit, digital signal processor (DSP), graphics processing unit (GPU), microcontroller, communication interface (Comm. I/F), memory controller, processing core and so on, but the external devices are not limited thereto, and may be of various types. The control logic 14 may identify a write command or a read command by decoding the command CMD. When the write command is identified, the control logic 14 may generate the row address ROW and the column address COL corresponding to the address ADDR to write the data DATA to the cell array 11, and generate the control signal CTR indicating a write operation. Further, when the read command is identified, the control logic 14 may generate the row address ROW and the column address COL corresponding to the address ADDR to read the data DATA from the cell array 11, and generate the control signal CTR indicating a read operation.

In some example implementations, the control logic 14 may receive command, address, and clock signals from external devices through each of a plurality of ports. Each port may operate independently. For example, the control logic 14 may receive a first command, a first address and a first clock signal through the first port (for example, the port A), and the control logic 14 may receive a second command, a second address and a second clock signal through a second port (for example, the port B). In this case, the control logic 14 may generate a first control signal, a first row address and a first column address synchronized to the first clock signal based on the first command and first the address, and generate a second control signal, a second row address and a second column address synchronized to the second clock signal based on the second command and the second address. In some example implementations, the characteristics of the first clock signal and the second clock signal may be the same or different. For example, the characteristics may be frequency, phase, or duty cycle. The DP-SRAM cell may be accessed simultaneously through two independent ports. For example, concurrent operations such as writing data through the first port while reading data through the second port are possible. The DP-SRAM cell may be particularly useful in applications that require simultaneous access to multiple data, such as high-performance computing systems, network equipment, and GPUs.

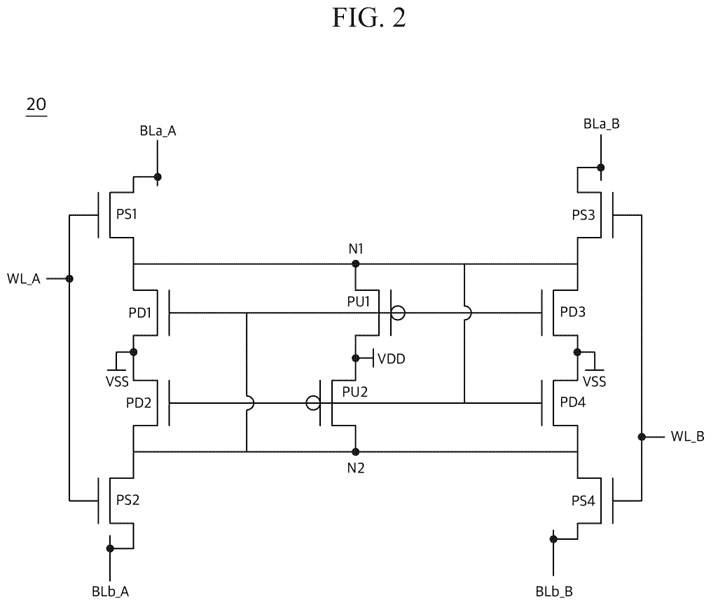

FIG. 2 is a circuit diagram illustrating a bit cell 20 according to some example implementations. The bit cell 20 of FIG. 2 may be an example of the bit line BC included in the integrated circuit 10 of FIG. 1. As illustrated in FIG. 2, the bit cell 20 may be a 10T SRAM cell (or the DP-SRAM cell) including 10 transistors. In some example implementations, the description of FIG. 2 may be equally applied to other bit cells included in the integrated circuit 10 of FIG. 1.

Referring to FIG. 2, the bit cell 20 may include a plurality of transistors. In some example implementations, the plurality of transistors may include a p-channel field effect transistor (PFET) and an n-channel field effect transistor (NFET). Among the plurality of transistors, a pass transistor may be connected to a word line and a bit line corresponding to the same port. When turned on by voltage applied to the gate through the activated word line, the pass transistor may connect a latch node and a bit line. Among the plurality of transistors, a pull-down transistor and a pull-up transistor may form an inverter, and a bit may be stored by the inverter pair cross-coupled between latch nodes. For example, the latch nodes may include a first data node N1 and a second data node N2 of FIG. 2.

In some example implementations, each of the plurality of pass transistors and the plurality of pull-down transistors may be an NFET, and each of the plurality of pull-up transistors may be a PFET. For example, as illustrated in FIG. 2, the plurality of pass transistors may include a first pass transistor PS1 to a fourth pass transistor PS4, the plurality of pull-down transistors may include a first pull-down transistor PD1 to a fourth pull-down transistor PD4, and the plurality of pull-up transistors may include a first pull-up transistor PU1 to a fourth pull-up transistor PU4. Meanwhile, the pass transistor may be referred to as an access transistor.

As illustrated in FIG. 2, the first pass transistor PS1, the first pull-down transistor PD1, a second pull-down transistor PD2 and a second pass transistor PS2 may be connected in series between a first bit line BLa_A and a first complementary bit line BLb_A. The first pass transistor PS1 and the first pull-down transistor PD1 may be connected through the first data node N1, and the second pass transistor PS2 and the second pull-down transistor PD2 may be connected through the second data node N2. A negative supply voltage VSS may be applied to the node to which the first pull-down transistor PD1 and the second pull-down transistor PD2 are connected. The first pull-up transistor PU1 and a second pull-up transistor PU2 may be connected in series between the first data node N1 and the second data node N2. A positive supply voltage VDD may be applied to the node to which the first pull-up transistor PU1 and the second pull-up transistor PU2 are connected. A third pass transistor PS3, a third pull-down transistor PD3, the fourth pull-down transistor PD4, and the fourth pass transistor PS4 may be connected in series between a second bit line BLa_B and a second complementary bit line BLb_B. The third pass transistor PS3 and the third pull-down transistor PD3 may be connected through the first data node N1, and the fourth pass transistor PS4 and the fourth pull-down transistor PD4 may be connected through the second data node N2. The negative supply voltage VSS may be applied to the node to which the third pull-down transistor PD3 and the fourth pull-down transistor PD4 are connected.

The gates of the first pull-up transistor PU1, the first pull-down transistor PD1 and the third pull-down transistor PD3 may be connected to each other, and be connected to the second data node N2. The gates of the second pull-up transistor PU2, the second pull-down transistor PD2 and the fourth pull-down transistor PD4 may be connected to each other, and be connected to the first data node N1.

In some example implementations, the first pull-down transistor PD1, the first pull-up transistor PU1 and the third pull-down transistor PD3 may correspond to a first inverter. The second pull-down transistor PD2, the second pull-up transistor PU2 and the fourth pull-down transistor PD4 may correspond to a second inverter. In other words, the first inverter may include the first pull-down transistor PD1, the first pull-up transistor PU1 and the third pull-down transistor PD3, and the second inverter may include the second pull-down transistor PD2, the second pull-up transistor PU2 and the fourth pull-down transistor PD4. The first inverter and the second inverter may correspond to inverters whose inputs and outputs are connected to each other, or, a cross-coupled inverter pair. In other words, the inverter pair may include a first inverter and a second inverter. For example, the input of the first inverter may be the second data node N2, and the output of the first inverter may be the first data node N1. The input of the second inverter may be the first data node N1, and the output of the second inverter may be the second data node N2.

The gates of the first pass transistor PS1 and the second pass transistor PS2 may be connected to the first word line WL_A corresponding to the first port. The first pass transistor PS1 and the second pass transistor PS2 may be connected to the first bit line pair corresponding to the first port. In some example implementations, the first bit line pair may include two bit lines, each transmitting and receiving complementary bits. For example, the first bit line pair BL_A of FIG. 1 may include the first bit line BLa_A and the first complementary bit line BLb_A of FIG. 2. As illustrated in FIG. 2, the first pass transistor PS1 may be connected to the first bit line BLa_A, and the second pass transistor PS2 may be connected to the first complementary bit line BLb_A. The gates of the third pass transistor PS3 and the fourth pass transistor PS4 may be connected to the second word line WL_B corresponding to the second port. The third pass transistor PS3 and the fourth pass transistor PS4 may be connected to the second bit line pair corresponding to the second port. In some example implementations, the second bit line pair may include two bit lines, each transmitting and receiving complementary bits. For example, the second bit line pair BL_B of FIG. 1 may include the second bit line BLa_B and the second complementary bit line BLb_B of FIG. 2. As illustrated in FIG. 2, the third pass transistor PS3 may be connected to the second bit line BLa_B, and the fourth pass transistor PS4 may be connected to the second complementary bit line BLb_B. In some example implementations, when the bit cell 20 performs a write operation or a read operation through the first port, the first word line WL_A corresponding to the first port may be activated, and the first pass transistor PS1 and the second pass transistor PS2 may be turned on. When the bit cell 20 performs a write operation or a read operation through the second port, the second word line WL_B corresponding to the second port may be activated, and the third pass transistor PS3 and the fourth pass transistor PS4 may be turned on. In other words, the bit line BC may be accessed independently through the first port and the second port respectively.

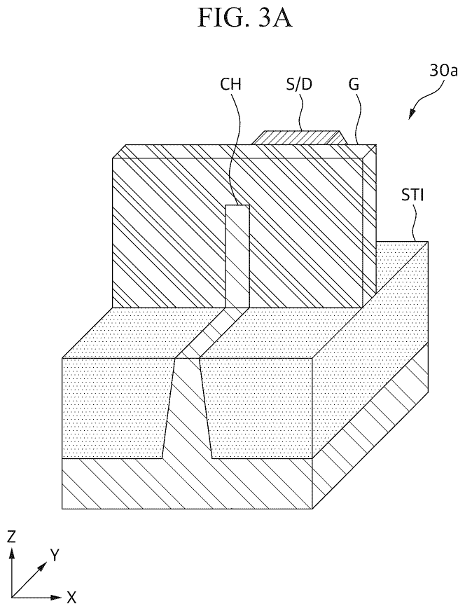

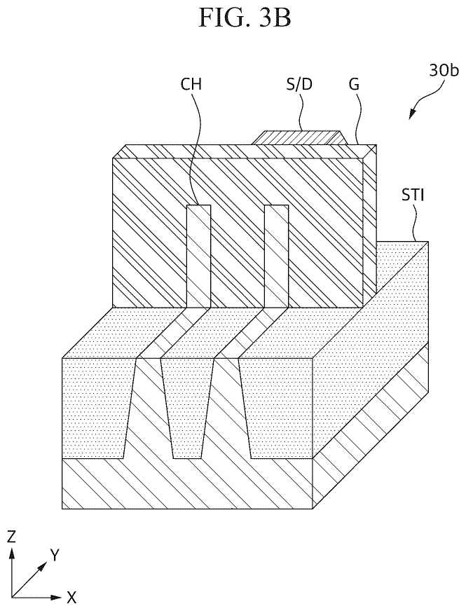

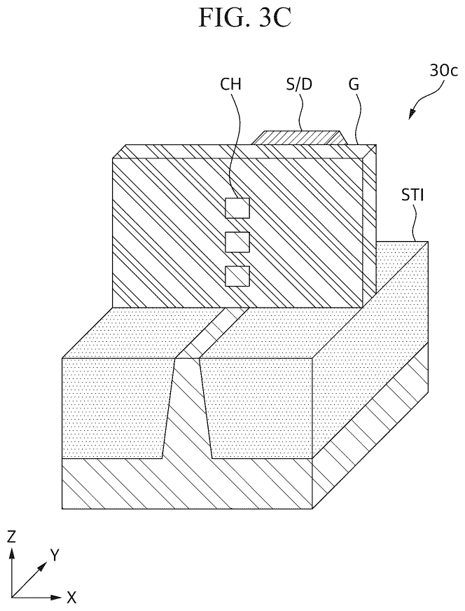

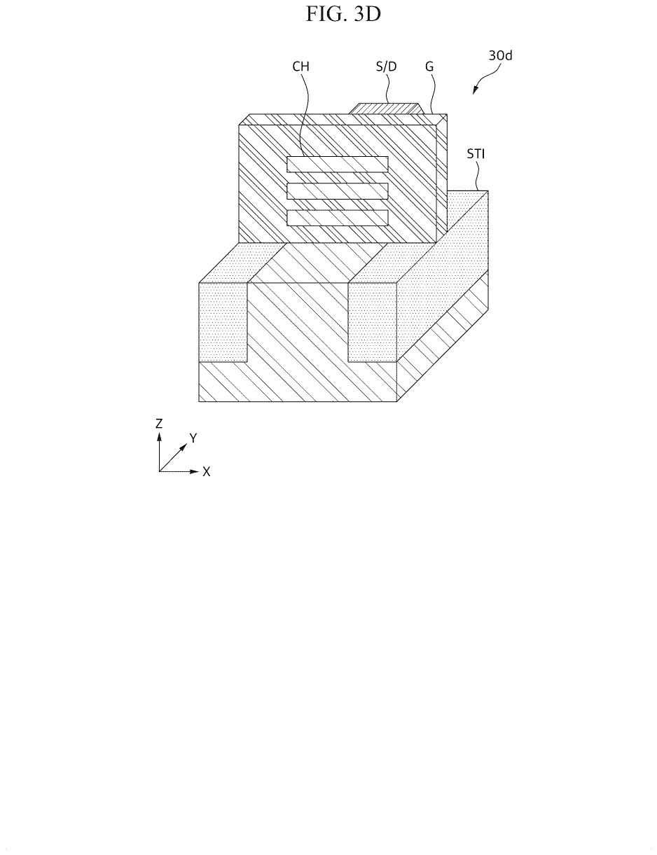

FIG. 3A to FIG. 3D are drawings illustrating transistors according to some example implementations. The drawings FIG. 3A through FIG. 3D illustrate example implementations of transistors included in the bit line BC of FIG. 1. For example, FIG. 3A illustrates a first FinFET 30a with one fin, FIG. 3B illustrates a second FinFET 30b with two fins, FIG. 3C illustrates a gate-all-around field effect transistor (GAAFET) 30c, and FIG. 3D illustrates a multi-bridge channel field effect transistor (MBCFET) 30d. For illustrative purposes, FIG. 3A to FIG. 3D illustrate one of the two source/drain regions removed.

Referring to FIG. 3A and FIG. 3B, in the shallow trench isolation (STI), the first FinFET 30a and the second FinFET 30b may be formed by a fin-shaped active pattern extending in the first direction (for example, the Y-axis direction) and a gate G extending in the second direction (for example, the X-axis direction). A source/drain S/D may be formed on both sides of the gate G, and accordingly, the source and the drain may be separated from each other in the first direction. A channel CH may be formed between the source and the drain. An insulating film may be formed between the channel CH and the gate G. The first FinFET 30a may be formed with a single fin-shaped active pattern, and the second FinFET 30b may have two fin-shaped active patterns. The two active patterns may be separated from each other in the second direction. Meanwhile, the number of active patterns is not limited to that illustrated in FIG. 3A and FIG. 3B, and may be changed to a different number.

Referring to FIG. 3C, the GAAFET 30c may be formed by active patterns, or, nanowires, extending in the first direction and spaced apart from each other in the third direction (for example, the Z-axis direction) and the gate G extending in the second direction. The source/drain S/D may be formed on both sides of the gate G, and accordingly, the source and drain may be separated from each other in the first direction. An insulating film may be formed between the channel CH and the gate G. Meanwhile, the number of nanowires is not limited to that illustrated in FIG. 3C, and may be changed to a different number.

Referring to FIG. 3D, the MBCFET 30d may be formed by active patterns, or, nanosheets, extending in the first direction and spaced apart from each other in the third direction, and the gate G extending in the second direction. The source/drain S/D may be formed on both sides of the gate G, and accordingly, the source and the drain may be separated from each other in the first direction. An insulating film may be formed between the channel CH and the gate G. Meanwhile, the number of nanosheets is not limited to that illustrated in FIG. 3D, and may be changed to a different number.

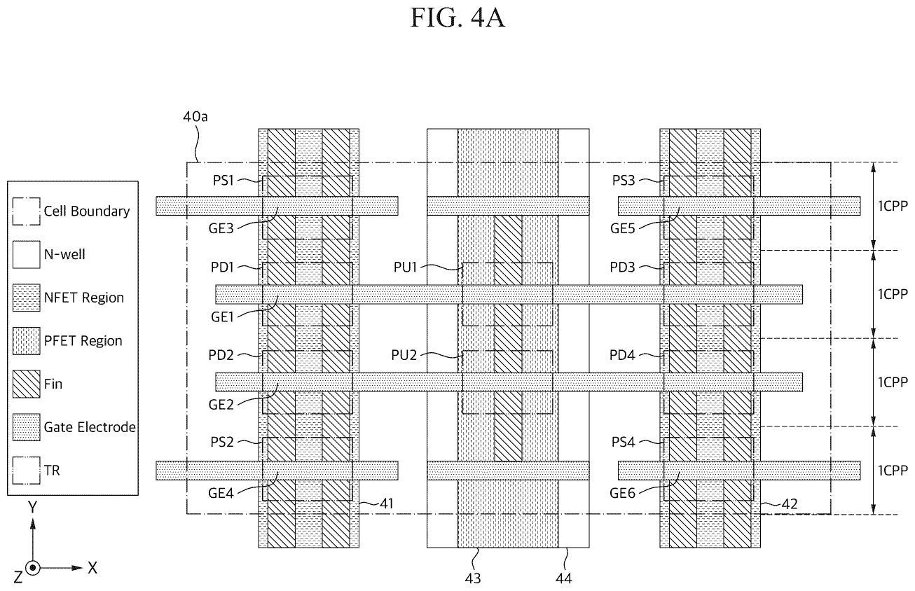

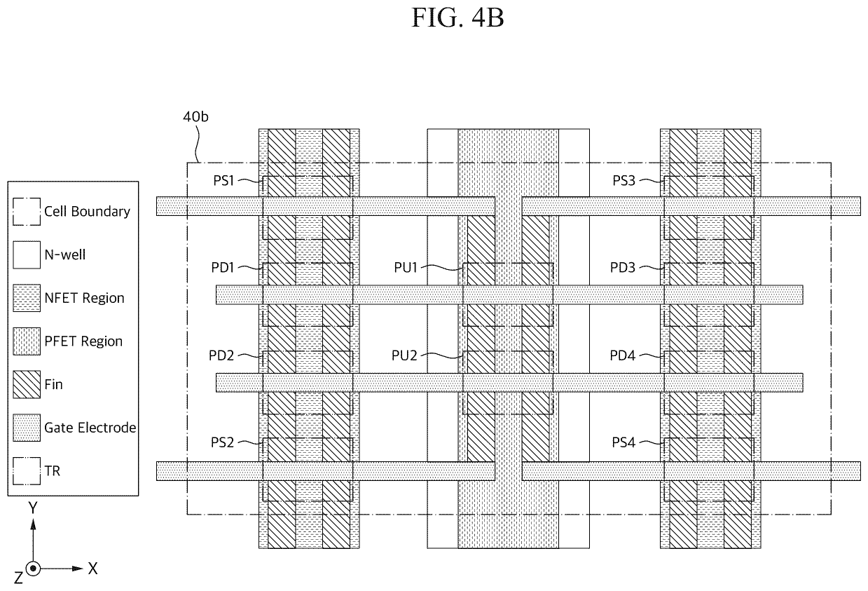

FIG. 4A and FIG. 4B are plan views illustrating a bit cell according to some example implementations. For example, the plan views of FIG. 4A and FIG. 4B illustrate layouts with different numbers of active patterns of transistors included in the bit cell 20 of FIG. 2.

Referring to FIG. 4A and FIG. 4B, a bit cell 40a and a bit cell 40b may include a plurality of transistors. Each transistor TR may include a gate electrode, a source, a drain, and a channel. Each transistor TR may be placed (or formed) in one of a plurality of active regions (or device regions). In some example implementations, each of the plurality of active regions may be extended in the first direction, and the plurality of active regions may be spaced apart from each other. In the present disclosure, something being “extended” may be understood as having a shape or form that is longer in the direction it extends compared to other directions, is not limited to straight lines, but may also be understood as shapes such as curves and waveforms. Meanwhile, the first direction may be referred to as the column direction, and the second direction may be referred to as the row direction.

In the present disclosure, the Y-axis direction and the X-axis direction may be referred to as the first direction and the second direction, respectively, and the Z-axis direction may be referred to as the vertical direction or the third direction. A plane having the X-axis and the Y-axis may be referred to as a horizontal plane, an element that is positioned in the +Z direction relative to other elements may be referred to as being above other elements, and an element that is positioned in the −Z direction relative to other elements may be referred to as being below the other elements. Further, the area of an element may refer to the size occupied by the element in a plane parallel to the horizontal plane, and the width of an element may refer to the length in a direction orthogonal to the direction in which the element extends. The surface exposed in the +Z direction may be referred to as the top surface, the surface exposed in the −Z direction may be referred to as the bottom surface, and surfaces exposed in the ±X direction or ±Y direction may be referred to as side surfaces. In the drawings of the present disclosure, for convenience of illustration, only some layers may be depicted, and a via connecting a parent pattern and a child pattern may be displayed for clarity even though it is located below the parent pattern. Further, a pattern composed of a conductive material, such as a pattern of an interconnection layer, may be referred to as a conductive pattern, or may be referred to simply as a pattern. In the present disclosure, elements that are electrically interconnected may be simply referred to as connected.

In some example implementations, the bit cell 40a and the bit cell 40b may include a plurality of active regions. The plurality of active regions may include a first active region 41, a second active region 42 and a third active region 43. In some example implementations, the bit cell 40a and the bit cell 40b may include a well region 44 extending in the first direction. The well region 44 may be formed on the substrate. The well region 44 may have a different conductivity type from the substrate, and the PFET region may extend in the first direction in the well region 44. For example, when the substrate is a p-type substrate, as in FIG. 4A and FIG. 4B, the first active region 41 and the second active region 42 may have p-type as NFET regions, the well region 44 may be n-type, and the third active region 43 may be n-type as a PFET region.

In some example implementations, the bit cell 40a and the bit cell 40b may include a plurality of gate electrodes. Each of the plurality of gate electrodes may be extended in the second direction. Sources/drains may be formed in the first direction on both sides of the gate electrode. The source/drain may be electrically connected to the pattern of the interconnection layer through the source/drain contacts, and the gate electrode may be electrically connected to the pattern of the interconnection layer through the gate contact.

In some example implementations, referring to FIG. 4A and FIG. 4B, the active patterns may be extended in the first direction. In each of the first active region 41 and the second active region 42, two active patterns may extend in the first direction. Referring to FIG. 4A, in the third active region 43 of the bit cell 40a, one active pattern may extend in the first direction. Referring to FIG. 4B, in the third active region 43 of the bit cell 40b, two active patterns may extend in the first direction. Meanwhile, not limited to the example implementations illustrated in the drawings, the shape and number of active patterns formed in each of the first active region 41 to the third active region 43 may be varied.

In some example implementations, in the first active region 41, the first pass transistor PS1, the first pull-down transistor PD1, the second pull-down transistor PD2 and the second pass transistor PS2 may be placed. The first pass transistor PS1 and the second pass transistor PS2 may be separated in the first direction, and the first pull-down transistor PD1 and the second pull-down transistor PD2 may be placed between the first pass transistor PS1 and the second pass transistor PS2. The first pass transistor PS1, the first pull-down transistor PD1, the second pull-down transistor PD2 and the second pass transistor PS2 may be connected sequentially. For example, the first pass transistor PS1 and the first pull-down transistor PD1 may share the source and/or drain. The first pull-down transistor PD1 and the second pull-down transistor PD2 may share the source. The second pull-down transistor PD2 and the second pass transistor PS2 may share the source and/or drain. In the present disclosure, a plurality of transistors arranged in the first active region 41 may be referred to as a plurality of first transistors.

In some example implementations, in the second active region 42, the third pass transistor PS3, the third pull-down transistor PD3, the fourth pull-down transistor PD4 and the fourth pass transistor PS4 may be placed. The third pass transistor PS3 and the fourth pass transistor PS4 may be separated in the first direction, and the third pull-down transistor PD3 and the fourth pull-down transistor PD4 may be placed between the third pass transistor PS3 and the fourth pass transistor PS4. The third pass transistor PS3, the third pull-down transistor PD3, the fourth pull-down transistor PD4 and the fourth pass transistor PS4 may be connected sequentially. For example, the third pass transistor PS3 and the third pull-down transistor PD3 may share the source and/or drain. The third pull-down transistor PD3 and the fourth pull-down transistor PD4 may share the source. The fourth pull-down transistor PD4 and the fourth pass transistor PS4 may share the source and/or drain. In the present disclosure, a plurality of transistors arranged in the second active region 42 may be referred to as a plurality of second transistors.

In some example implementations, the first pull-up transistor PU1 and the second pull-up transistor PU2 may be placed in the third active region 43. The first pull-up transistor PU1 and the second pull-up transistor PU2 may be separated in the first direction. The first pull-up transistor PU1 may be separated from the first pull-down transistor PD1 (or the third pull-down transistor PD3) in the second direction. The second pull-up transistor PU2 may be separated from the second pull-down transistor PD2 (or the fourth pull-down transistor PD4) in the second direction. In the present disclosure, a plurality of transistors arranged in the third active region 43 may be referred to as a plurality of third transistors.

In some example implementations, the bit cell 40a and the bit cell 40b may include a first gate electrode GE1 to a sixth gate electrode GE6. As illustrated in FIG. 4A and FIG. 4B, the first pull-down transistor PD1, the first pull-up transistor PU1 and the third pull-down transistor PD3 may share the first gate electrode GE1, which extends in the second direction. The second pull-down transistor PD2, the second pull-up transistor PU2 and the fourth pull-down transistor PD4 may share a second gate electrode GE2, which extends in the second direction. The first pass transistor PS1 to the fourth pass transistor PS4 may be formed by a third gate electrode GE3 to the sixth gate electrode GE6, respectively. In the present disclosure, transistors “sharing a gate electrode” may be understood as meaning that the gates of the transistors are formed by a single gate electrode. Meanwhile, the present disclosure is not limited to transistors sharing one gate electrode, and separate gate electrodes may be electrically interconnected through the pattern of the interconnection layer and so on.

In some example implementations, the number of plurality of first transistors arranged in the first active region 41 may be equal to the number of plurality of second transistors arranged in the second active region 42. The number of plurality of third transistors arranged in the third active region 43 may be less than the number of plurality of first transistors or the number of plurality of second transistors. For example, the number of first transistors may be 4, the number of second transistors may be 4, and the number of third transistors may be 2. As illustrated in FIG. 4A and FIG. 4B, the four first transistors (or the four second transistors) may be arranged in the first direction, and accordingly, the bit cell 40a and the bit cell 40b may have a length of 4CPP (contact-poly-pitch) in the first direction, and the CPP may correspond to the pitch of gate electrodes.

In some example implementations, the first active region 41 and the second active region 42 may be spaced apart from each other with the well region 44 interposed therebetween. The distance between the first active region 41 and the well region 44 may be equal to the distance between the second active region 42 and the well region 44. In this case, the first transistor of the first active region 41 and the second transistor of the second active region 42 may receive substantially the same local layout effect and/or well-proximity effect. The variation in electrical characteristics (for example, threshold voltage, channel doping distribution and so on) between the first transistor and the second transistor may be reduced. Thus, the bit cell 40a and the bit cell 40b may have improved match characteristics.

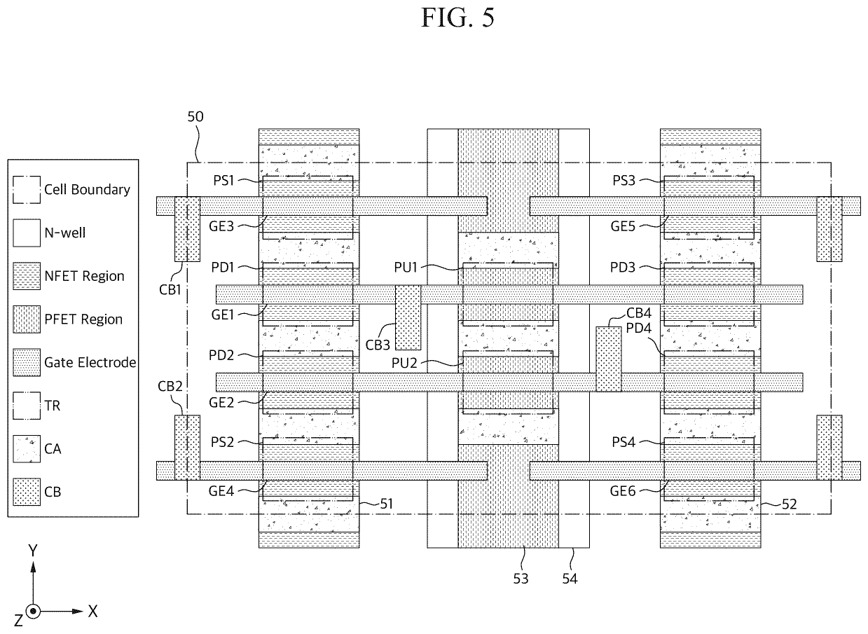

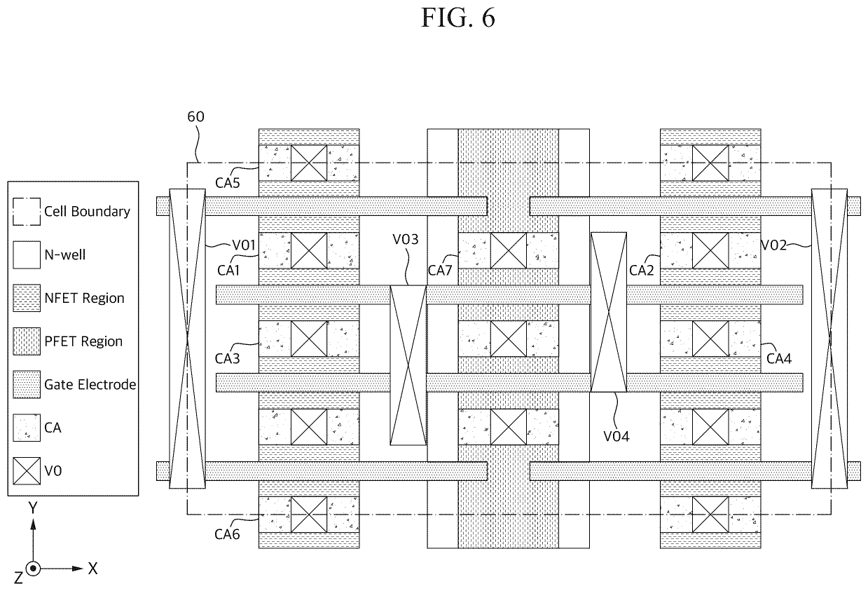

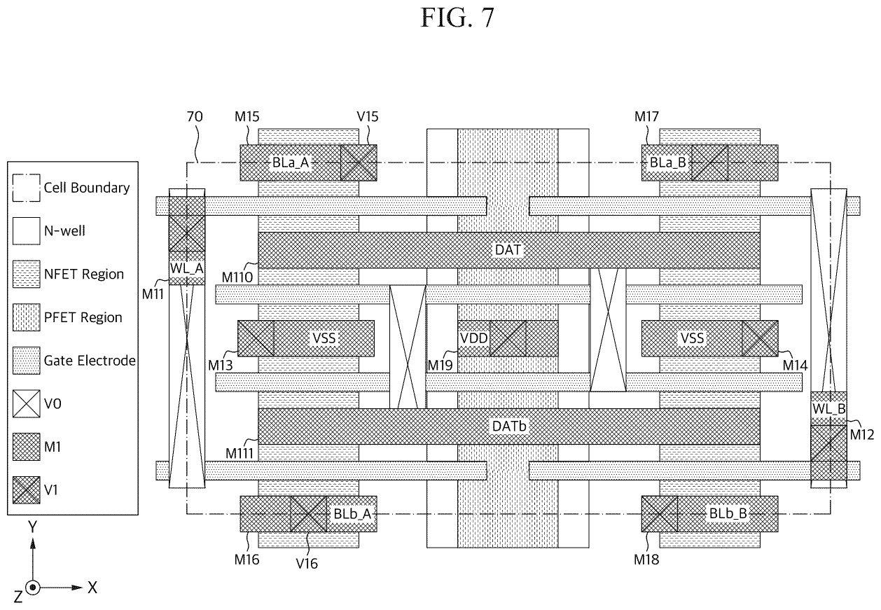

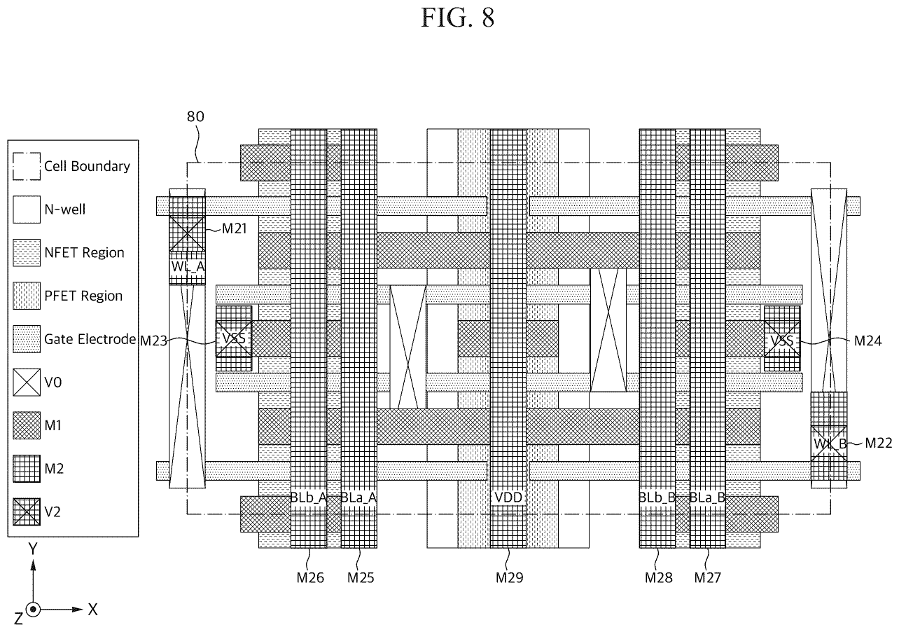

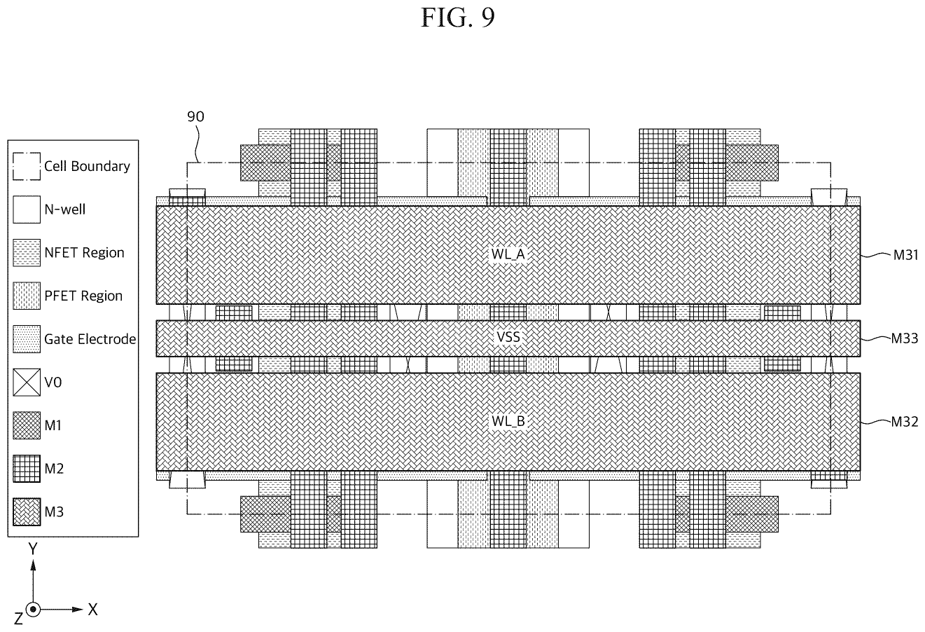

FIG. 5 to FIG. 9 are plan views illustrating the layout of bit cells according to some example implementations. For example, the plan views of FIG. 5 to FIG. 9 represent layouts corresponding to the bit line BC of FIG. 1 or the bit cell 20 of FIG. 2. FIG. 5 illustrates a layout of a bit cell 50 where a source/drain contact CA and a gate contact CB are formed on the layout having the structures of the bit cell 40a and the bit cell 40b of FIG. 4A and FIG. 4B or an active pattern structure different therefrom. FIG. 6 illustrates the layout of a bit cell 60 in which vias of a first via layer V0 are formed in the bit cell 50 of FIG. 5. FIG. 7 illustrates the layout of a bit cell 70 in which patterns of a first interconnection layer M1 and vias of a second via layer V1 are formed in the bit cell 60 of FIG. 6. FIG. 8 illustrates the layout of a bit cell 80 in which patterns of a second interconnection layer M2 and vias of a third via layer V2 are formed in the bit cell 70 of FIG. 7. FIG. 9 illustrates a plan view of a bit cell 90 in which patterns of a third interconnection layer M3 are formed in the bit cell 80 of FIG. 8. Meanwhile, the bit cell 20 of FIG. 2 is not limited to the layouts of FIG. 5 to FIG. 9, and may also be applied to example implementations of various layouts.

Referring to FIG. 5 to FIG. 9, the bit cell 50, the bit cell 60, the bit cell 70, the bit cell 80 and the bit cell 90 may include a first active region 51 to a third active region 53. The bit cell 50, the bit cell 60, the bit cell 70, the bit cell 80 and the bit cell 90 may include a plurality of first transistors arranged in the first active region 51, a plurality of second transistors placed in a second active region 52 and a plurality of third transistors placed in the third active region 53. The second active region 52 may be spaced in the second direction from the first active region 51, and the third active region 53 may be placed between the first active region 51 and the second active region 52. For example, the third active region 53 may be placed in the center regions of the bit cell 50, the bit cell 60, the bit cell 70, the bit cell 80 and the bit cell 90, and the first active region 51 and the second active region 52 may be placed in the edge areas of the bit cell 50, the bit cell 60, the bit cell 70, the bit cell 80 and the bit cell 90.

In some example implementations, the plurality of first transistors may be arranged in the first direction, and may include the first pass transistor PS1, the first pull-down transistor PD1, the second pull-down transistor PD2 and the second pass transistor PS2 that are connected in series with each other. The plurality of second transistors may be placed in the first direction, and may include the third pass transistor PS3, the third pull-down transistor PD3, the fourth pull-down transistor PD4 and the fourth pass transistor PS4, which are connected in series with each other. The plurality of third transistors may be placed in the first direction, and include the first pull-up transistor PU1 and the second pull-up transistor PU2 that are connected in series with each other. In some example implementations, the first pull-down transistor PD1, the first pull-up transistor PU1 and the third pull-down transistor PD3 may share the first gate electrode GE1, which extends in the second direction. The second pull-down transistor PD2, the second pull-up transistor PU2 and the fourth pull-down transistor PD4 may share the second gate electrode GE2, which extends in the second direction.

In some example implementations, the first pass transistor PS1 may be connected between the first inverter and the first bit line BLa_A. For example, the first pass transistor PS1 may be connected to the drains of the first pull-down transistor PD1, the first pull-up transistor PU1 and the third pull-down transistor PD3 included in the first inverter, and may be connected to the pattern corresponding to the first bit line BLa_A. The second pass transistor PS2 may be connected between the second inverter and the first complementary bit line BLb_A. For example, the second pass transistor PS2 may be connected to the drains of the second pull-down transistor PD2, the second pull-up transistor PU2 and the fourth pull-down transistor PD4 included in the second inverter, and may be connected to the pattern corresponding to the first complementary bit line BLb_A. The third pass transistor PS3 may be connected between the first inverter and the second bit line BLa_B, and the fourth pass transistor PS4 may be connected between the second inverter and the second complementary bit line BLb_B. The above description may be equally applied to the third pass transistor PS3 and the fourth pass transistor PS4.

In some example implementations, the bit cell 50, the bit cell 60, the bit cell 70, the bit cell 80 and the bit cell 90 may include at least one of the source/drain contact CA formed on the source/drain of the transistor and the gate contact CB formed on the gate electrode. The bit cell 50, the bit cell 60, the bit cell 70, the bit cell 80 and the bit cell 90 may include at least one of vias of the first via layer V0 formed on the contact, patterns of the first interconnection layer M1 formed on the first via layer V0, vias of the second via layer V1 formed on the first interconnection layer M1, patterns of the second interconnection layer M2 formed on top of the second via layer V1, vias of the third via layer V2 formed on top of the second interconnection layer M2, and patterns of the third interconnection layer M3 formed on top of the third via layer V2. In some example implementations, the source/drain contact CA and/or the gate contact CB may be connected to the pattern of the first interconnection layer M1 without going through the via of the first via layer V0.

Referring to FIG. 5 to FIG. 9, a first pattern M31 of the third interconnection layer M3 may correspond to the first word line WL_A. For example, the first pattern M31 of the third interconnection layer M3 may be electrically connected to the first word line WL_A or the first word line WL_A corresponding to the first port. As illustrated in FIG. 9, the first pattern M31 of the third interconnection layer M3 may be extended in the second direction. The first pattern M31 of the third interconnection layer M3 may be electrically connected to the third gate electrode GE3 of the first pass transistor PS1 and a fourth gate electrode GE4 of the second pass transistor PS2. A control signal corresponding to the first port may be applied to the first pattern M31 of the third interconnection layer M3, and depending on the applied control signal, the first pass transistor PS1 and the second pass transistor PS2 may be turned on or off together.

In some example implementations, through a first via V01 of the first via layer V0, a first pattern M11 of the first interconnection layer M1 and a first pattern M21 of the second interconnection layer M2, the first pattern M31 of the third interconnection layer M3 may be electrically connected to the third gate electrode GE3 of the first pass transistor PS1 and the fourth gate electrode GE4 of the second pass transistor PS2. Referring to FIG. 5 and FIG. 6, the third gate electrode GE3 of the first pass transistor PS1 and the fourth gate electrode GE4 of the second pass transistor PS2 may be connected to each other through the first via V01 of the first via layer V0. The first via V01 of the first via layer V0 may be formed on a first gate contact CB1 and a second gate contact CB2, and may be extended in the first direction to be electrically connected to the first gate contact CB1 and the second gate contact CB2. The third gate electrode GE3 of the first pass transistor PS1 and the fourth gate electrode GE4 of the second pass transistor PS2 may be extended in the second direction, and the first gate contact CB1 and the second gate contact CB2 may be formed on the third gate electrode GE3 of the first pass transistor PS1 and the fourth gate electrode GE4 of the second pass transistor PS2 in a region spaced apart from the first active region 51 in the second direction. Referring to FIG. 6 and FIG. 7, the first pattern M11 of the first interconnection layer M1 may be formed on the first via V01 of the first via layer V0, a via of the second via layer V1 may be formed between the first pattern M11 of the first interconnection layer M1 and the first pattern M21 of the second interconnection layer M2, and a via of the third via layer V2 may be formed between the first pattern M21 of the second interconnection layer M2 and the first pattern M31 of the third interconnection layer M3.

Referring to FIG. 5 to FIG. 9, a second pattern M32 of the third interconnection layer M3 may correspond to the second word line WL_B. For example, the second pattern M32 of the third interconnection layer M3 may be electrically connected to the second word line WL_B or the second word line WL_B corresponding to the second port. The second pattern M32 of the third interconnection layer M3 may be spaced from the first pattern M31 of the third interconnection layer M3 in the first direction, and extended in the second direction. The second pattern M32 of the third interconnection layer M3 may be electrically connected to a fifth gate electrode GE5 of the third pass transistor PS3 and the sixth gate electrode GE6 of the fourth pass transistor PS4. A control signal corresponding to the second port may be applied to the second pattern M32 of the third interconnection layer M3, and depending on the applied control signal, the third pass transistor PS3 and the fourth pass transistor PS4 may be turned on or off together.

In some example implementations, through a second via V02 of the first via layer V0, a second pattern M12 of the first interconnection layer M1, and a second pattern M22 of the second interconnection layer M2, the second pattern M32 of the third interconnection layer M3 may be electrically connected to the fifth gate electrode GE5 of the third pass transistor PS3 and the sixth gate electrode GE6 of the fourth pass transistor PS4. The description of the first via V01 of the first via layer V0, the first pattern M11 of the first interconnection layer M1, and the first pattern M21 of the second interconnection layer M2 may be applied equally to the second via V02 of the first via layer V0, the second pattern M12 of the first interconnection layer M1, and the second pattern M22 of the second interconnection layer M2.

Referring to FIG. 5 to FIG. 9, a third pattern M33 of the third interconnection layer M3 may correspond to a power line configured to apply the negative supply voltage VSS. For example, referring to FIG. 9, the third pattern M33 of the third interconnection layer M3 may be a power line providing the negative supply voltage VSS or a pattern electrically connected to the power line. The third pattern M33 of the third interconnection layer M3 may be extended in the second direction. In some example implementations, the third pattern M33 of the third interconnection layer M3 may be configured to apply the negative supply voltage VSS to the first pull-down transistor PD1 to the fourth pull-down transistor PD4.

In some example implementations, the third pattern M33 of the third interconnection layer M3 may be placed between the first pattern M31 and the second pattern M32 of the third interconnection layer M3. Accordingly, the third pattern M33 of the third interconnection layer M3 corresponding to the negative supply voltage VSS may shield the first pattern M31 of the third interconnection layer M3 corresponding to the first word line WL_A and the second pattern M32 of the third interconnection layer M3 corresponding to the second word line WL_B, and thus the electrical interference between the first word line WL_A and the second word line WL_B may be reduced. Meanwhile, due to the length of the first direction of the bit cell 90 (in other words, 4CPP), expanded may be the width of each of the first pattern M31 of the third interconnection layer M3 corresponding to the first word line WL_A and the second pattern M32 of the third interconnection layer M3 corresponding to the second word line WL_B. Accordingly, the resistance of each of the first pattern M31 of the third interconnection layer M3 and the second pattern M32 of the third interconnection layer M3 may be reduced.

In some example implementations, the third pattern M33 of the third interconnection layer M3 may be electrically connected to the first pull-down transistor PD1 and the second pull-down transistor PD2 through a third pattern M13 of the first interconnection layer M1 and a third pattern M23 of the second interconnection layer M2 corresponding to the negative supply voltage VSS, and the third pattern M33 of the third interconnection layer M3 may be electrically connected to the third pull-down transistor PD3 and the fourth pull-down transistor PD4 through a fourth pattern M14 of the first interconnection layer M1 and a fourth pattern M24 of the second interconnection layer M2 corresponding to the negative supply voltage VSS.

For example, referring to FIG. 5, the first pull-down transistor PD1 and the second pull-down transistor PD2 may share the source, and the third pull-down transistor PD3 and the fourth pull-down transistor PD4 may share the source. In other words, the first pull-down transistor PD1 and the second pull-down transistor PD2 may have a common source, and the third pull-down transistor PD3 and the fourth pull-down transistor PD4 may have a common source.

Referring to FIG. 5 and FIG. 6, a third source/drain contact CA3 may be formed on the common source of the first pull-down transistor PD1 and the second pull-down transistor PD2, and a fourth source/drain contact CA4 may be formed on the common source of the third pull-down transistor PD3 and the fourth pull-down transistor PD4. Vias of the first via layer V0 may be formed on the third source/drain contact CA3 and the fourth source/drain contact CA4. Referring to FIG. 6 and FIG. 7, the third pattern M13 of the first interconnection layer M1 may be formed on the via of the first via layer V0 formed on the third source/drain contact CA3, and the fourth pattern M14 of the first interconnection layer M1 may be formed on the via of the first via layer V0 formed on the fourth source/drain contact CA4. Vias of the second via layer V1 may be formed on the third pattern M13 and the fourth pattern M14 of the first interconnection layer M1. Referring to FIG. 7 and FIG. 8, the third pattern M23 of the second interconnection layer M2 may be formed on the via of the second via layer V1 formed on the third pattern M13 of the first interconnection layer M1, and the fourth pattern M24 of the second interconnection layer M2 may be formed on the via of the second via layer V1 formed on the fourth pattern M14 of the first interconnection layer M1. Vias of the third via layer V2 may be formed on the third pattern M23 and the fourth pattern M24 of the second interconnection layer M2. Referring to FIG. 8 and FIG. 9, the third pattern M33 of the third interconnection layer M3 may be formed on the vias of the third via layer V2 in the regions where the third pattern M23 and the fourth pattern M24 of the second interconnection layer M2 are formed, and may be extended in the second direction to be electrically connected to them.

Referring to FIG. 5 to FIG. 9, a fifth pattern M25 of the second interconnection layer M2 may correspond to the first bit line BLa_A. For example, the fifth pattern M25 of the second interconnection layer M2 may be the first bit line BLa_A corresponding to the first port, or a pattern electrically connected to the first bit line BLa_A. The fifth pattern M25 of the second interconnection layer M2 may be electrically connected to the first pass transistor PS1, and may be extended in the first direction. A first via V15 and a second via V16 of the second via layer V1 may be spaced apart from each other in the second direction. A sixth pattern M26 of the second interconnection layer M2 may correspond to the first complementary bit line BLb_A. For example, the sixth pattern M26 of the second interconnection layer M2 may be the first complementary bit line BLb_A corresponding to the first port, or may be a pattern electrically connected to the first complementary bit line BLb_A. The fifth pattern M25 and the sixth pattern M26 of the second interconnection layer M2 may correspond to the bit line pair of the same port. The sixth pattern M26 of the second interconnection layer M2 may be electrically connected to the second pass transistor PS2 and may be extended in the first direction. The sixth pattern M26 of the second interconnection layer M2 may be spaced in the second direction from the fifth pattern M25 of the second interconnection layer M2. The sixth pattern M26 of the second interconnection layer M2 may be configured to transmit a bit complementary to a bit transmitted by the fifth pattern M25 of the second interconnection layer M2.

In some example implementations, the fifth pattern M25 of the second interconnection layer M2 may be electrically connected to the first pass transistor PS1 through a fifth pattern M15 of the first interconnection layer M1 and the first via V15 of the second via layer V1, and the sixth pattern M26 of the second interconnection layer M2 may be electrically connected to the second pass transistor PS2 through a sixth pattern M16 of the first interconnection layer M1 and the second via V16 of the second via layer V1. For example, referring to FIG. 5 and FIG. 6, a fifth source/drain contact CA5 may be formed on the source/drain corresponding to the first access node of the first pass transistor PS1, and a via of the first via layer V0 may be formed on top of the fifth source/drain contact CA5. A sixth source/drain contact CA6 may be formed on the source/drain corresponding to the second access node of the second pass transistor PS2, and a via of the first via layer V0 may be formed on top of the sixth source/drain contact CA6. Referring to FIG. 6 and FIG. 7, the fifth pattern M15 of the first interconnection layer M1 may be formed on the via of the first via layer V0 formed on the fifth source/drain contact CA5, and the first via V15 of the second via layer V1 may be formed on the fifth pattern M15 of the first interconnection layer M1. The sixth pattern M16 of the first interconnection layer M1 may be formed on the first via layer V0, which is formed on the sixth source/drain contact CA6, and the second via V16 of the second via layer V1 may be formed on the sixth pattern M16 of the first interconnection layer M1. Referring to FIG. 7 and FIG. 8, the fifth pattern M25 of the second interconnection layer M2 may be formed on the first via V15 of the second via layer V1, and be extended in the first direction. The sixth pattern M26 of the second interconnection layer M2 may be formed on the second via V16 of the second via layer V1, and be extended in the first direction. The first via V15 and the second via V16 of the second via layer V1 may be mutually spaced in the second direction, and accordingly, the fifth pattern M25 and the sixth pattern M26 of the second interconnection layer M2 may be mutually spaced in the second direction.

A seventh pattern M27 of the second interconnection layer M2 may correspond to the second bit line BLa_B, and an eighth pattern M28 of the second interconnection layer M2 may correspond to the second complementary bit line BLb_B. For example, the seventh pattern M27 of the second interconnection layer M2 may be the second bit line BLa_B corresponding to the second port, or may be a pattern electrically connected to the second bit line BLa_B. For example, the eighth pattern M28 of the second interconnection layer M2 may be the second complementary bit line BLb_B corresponding to the second port, or may be a pattern electrically connected to the second complementary bit line BLb_B. The seventh pattern M27 of the second interconnection layer M2 may be electrically connected to the third pass transistor PS3, and be extended in the first direction. The seventh pattern M27 of the second interconnection layer M2 may be spaced in the second direction from the fifth pattern M25 and the sixth pattern M26 of the second interconnection layer M2. The eighth pattern M28 of the second interconnection layer M2 is electrically connected to the fourth pass transistor PS4 and may be extended in the first direction. The eighth pattern M28 of the second interconnection layer M2 may be spaced in the second direction from the seventh pattern M27 of the second interconnection layer M2. The eighth pattern M28 of the second interconnection layer M2 may be configured to transmit a bit complementary to a bit transmitted by the seventh pattern M27 of the second interconnection layer M2. In some example implementations, the seventh pattern M27 of the second interconnection layer M2 may be electrically connected to the third pass transistor PS3 through a seventh pattern M17 of the first interconnection layer M1 and the via of the second via layer V1, and the eighth pattern M28 of the second interconnection layer M2 may be electrically connected to the fourth pass transistor PS4 through an eighth pattern M18 of the first interconnection layer M1 and the via of the second via layer V1.

In some example implementations, the first distance between the fifth pattern M25 and the sixth pattern M26 of the second interconnection layer M2 may be shorter than the second distance between the fifth pattern M25 and the seventh pattern M27 (or the eighth pattern M28) of the second interconnection layer M2. In some example implementations, the third distance between the seventh pattern M27 and the eighth pattern M28 of the second interconnection layer M2 may be shorter than the second distance. Accordingly, bit lines included in a bit line pair corresponding to the same port may be arranged more adjacently.

Referring to FIG. 5 to FIG. 9, a ninth pattern M29 of the second interconnection layer M2 may correspond to a power line configured to apply the positive supply voltage VDD. For example, referring to FIG. 8, the ninth pattern M29 of the second interconnection layer M2 may be a power line that applies the positive supply voltage VDD or a pattern electrically connected to the power line. The ninth pattern M29 of the second interconnection layer M2 may be extended in the first direction. In some example implementations, the ninth pattern M29 of the second interconnection layer M2 may be placed between any one of the fifth pattern M25 and the sixth pattern M26 of the second interconnection layer M2 and any one of the seventh pattern M27 and the eighth pattern M28. In some example implementations, the ninth pattern M29 of the second interconnection layer M2 may be configured to apply the positive supply voltage VDD to the first pull-up transistor PU1 and the second pull-up transistor PU2. In some example implementations, the first pull-up transistor PU1 and the second pull-up transistor PU2 may have a common source, the source/drain contact CA, a via of the first via layer V0, a ninth pattern M19 of the first interconnection layer M1, a via of the second via layer V1, and the ninth pattern M29 of the second interconnection layer M2 may be sequentially formed on the common source of the first pull-up transistor PU1 and the second pull-up transistor PU2.

The ninth pattern M29 of the second interconnection layer M2 that applies a positive supply voltage and the third pattern M33 of the third interconnection layer M3 that applies a negative supply voltage may be located at different heights in the third direction, and may extend in directions intersecting each other. Each of the plurality of bit cells may include the ninth pattern M29 of the second interconnection layer M2 and the third pattern M33 of the third interconnection layer M3 that intersect each other, which may correspond to a power mesh. Meanwhile, the names of the first to ninth patterns described above are listed in the order in which they are explained, and names corresponding thereto in a claim may be listed differently depending on the order in which they appear in the claim.

Referring to FIG. 5 to FIG. 9, the bit cell 50, the bit cell 60, the bit cell 70, the bit cell 80 and the bit cell 90 may include first interconnection and second interconnection. In some example implementations, the first interconnection may be electrically connected to the drains of the first pull-down transistor PD1, the first pull-up transistor PU1 and the third pull-down transistor PD3, and may be electrically connected to the second gate electrode GE2. The second gate electrode GE2 extends in the second direction, and may be the gate electrode shared by the second pull-down transistor PD2, the second pull-up transistor PU2, and the fourth pull-down transistor PD4. The first interconnection may correspond to the first data node N1 of FIG. 2, to which the first pull-down transistor PD1, the first pull-up transistor PU1, and the third pull-down transistor PD3 are connected, and the second gate electrode GE2 may correspond to the gates of the first pull-down transistor PD1, the first pull-up transistor PU1 and the third pull-down transistor PD3, which are interconnected as described above in FIG. 2. In some example implementations, the second interconnection may be electrically connected to the drains of the second pull-down transistor PD2, the second pull-up transistor PU2 and the fourth pull-down transistor PD4, and be electrically connected to the first gate electrode GE1. The first gate electrode GE1 may be extended in the second direction, and may be the gate electrode shared by the first pull-down transistor PD1, the first pull-up transistor PU1 and the third pull-down transistor PD3. The second interconnection may correspond to the second data node N2 of FIG. 2, to which the second pull-down transistor PD2, the second pull-up transistor PU2 and the fourth pull-down transistor PD4 are connected, and the first gate electrode GE1 may correspond to the gates of the second pull-down transistor PD2, the second pull-up transistor PU2 and the fourth pull-down transistor PD4, which are interconnected as described above in FIG. 2. In some example implementations, the first interconnection may be a connection corresponding to the first data node N1 of FIG. 2, and the second interconnection may be a connection corresponding to the second data node N2 of FIG. 2.

For example, the first interconnection may correspond to a first bit BIT, and may include a fourth via V04 of the first via layer V0 in FIG. 6 and a tenth pattern M110 of the first interconnection layer M1 in FIG. 7. The drains of the first pull-down transistor PD1, the first pull-up transistor PU1 and the third pull-down transistor PD3 may be interconnected through the tenth pattern M110 of the first interconnection layer M1. The tenth pattern M110 of the first interconnection layer M1 may be electrically connected to the fourth via V04 of the first via layer V0, which is electrically connected to the second gate electrode GE2. Referring to FIG. 5 and FIG. 6, the fourth via V04 of the first via layer V0 may be formed on top of a fourth gate contact CB4. The fourth gate contact CB4 may be formed on the second gate electrode GE2 between the second active region 52 and the third active region 53. In order for the fourth via V04 of the first via layer V0 to be electrically connected to the tenth pattern M110 of the first interconnection layer M1 corresponding to first data DAT, at least one of the fourth via V04 and the fourth gate contact CB4 of the first via layer V0 may extend in the first direction. Referring to FIG. 5 and FIG. 6, a first source/drain contact CA1, a second source/drain contact CA2 and a seventh source/drain contact CA7 may be formed on the drains of the first pull-down transistor PD1, the third pull-down transistor PD3 and the first pull-up transistor PU1. Vias of the first via layer V0 may be formed on top of the first source/drain contact CA1, the second source/drain contact CA2 and the seventh source/drain contact CA7. Referring to FIG. 6 and FIG. 7, the tenth pattern M110 of the first interconnection layer M1 corresponding to the first data DAT may be formed on the vias of the first via layer V0 formed on the first source/drain contact CA1, the second source/drain contact CA2 and the seventh source/drain contact CA7, and may be extended in the second direction to be electrically connected therewith.

The second interconnection may correspond to the second bit, and may include a third via V03 of the first via layer V0 in FIG. 6 and an eleventh pattern M111 of the first interconnection layer M1 in FIG. 7. The drains of the second pull-down transistor PD2, the second pull-up transistor PU2 and the fourth pull-down transistor PD4 may be interconnected through the eleventh pattern M111 of the first interconnection layer M1, and the eleventh pattern M111 of the first interconnection layer M1 may be electrically connected to the third via V03 of the first via layer V0, which is electrically connected to the first gate electrode GE1. The third via V03 of the first via layer V0 may be formed on top of a third gate contact CB3. The third gate contact CB3 may be formed on the first gate electrode GE1 between the first active region 51 and the second active region 52. The description of the first interconnection above may be equally applied to the second interconnection.

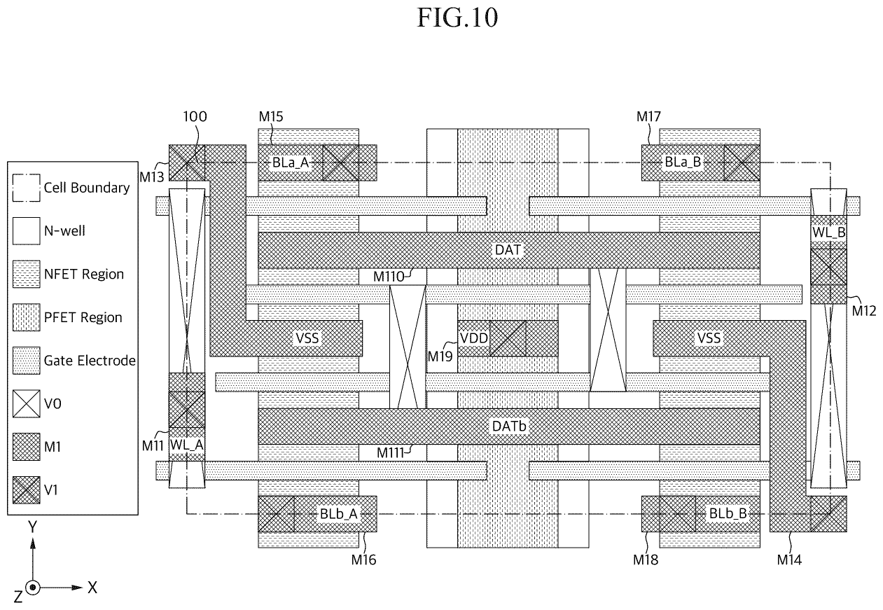

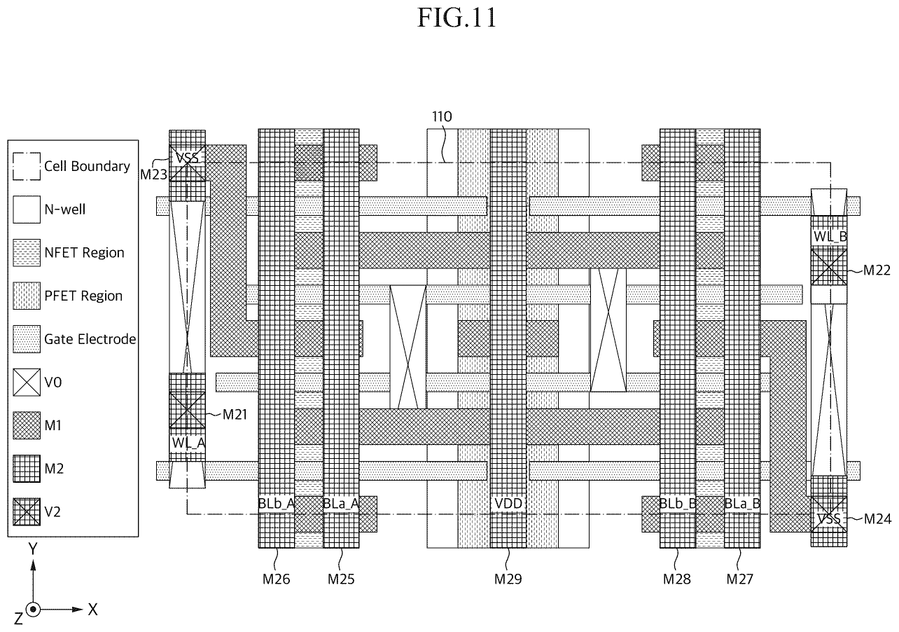

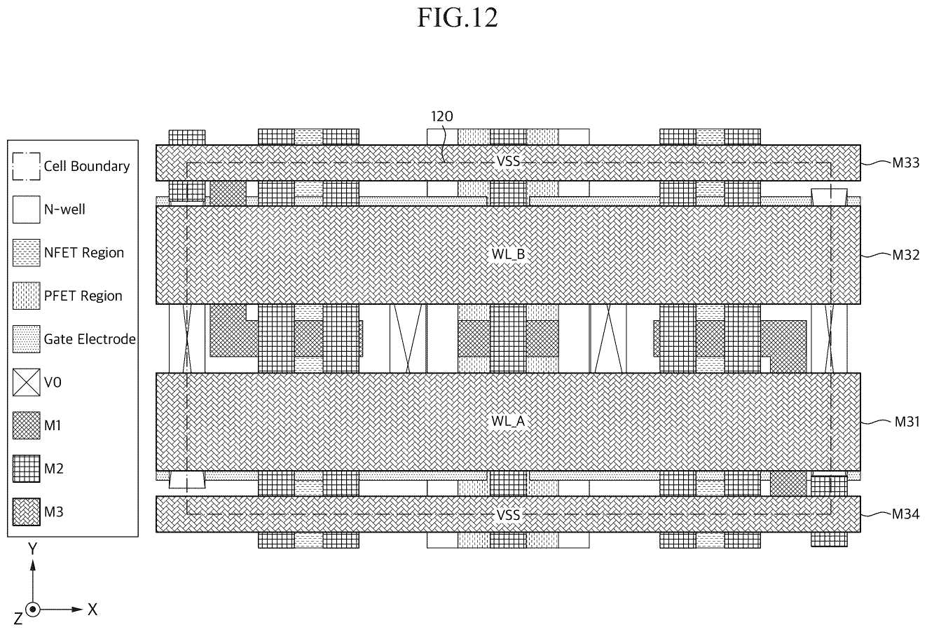

FIG. 10 to FIG. 12 are plan views illustrating the layout of bit cells according to some example implementations. For example, the plan views of FIG. 10 to FIG. 12 illustrate the layouts. FIG. 10 illustrates the layout of a bit cell 100 in which the first interconnection layer M1 and the second via layer V1 are formed in the bit cell 60 of FIG. 6. FIG. 11 illustrates the layout of a bit cell 110 in which the second interconnection layer M2 and the third via layer V2 are formed in the bit cell 100 of FIG. 10. FIG. 12 illustrates the layout of a bit cell 120 in which the third interconnection layer M3 is formed in the bit cell 120 of FIG. 11.

Referring to FIG. 10 to FIG. 12, the bit cell 100, the bit cell 110 and the bit cell 120 may include at least one of vias of the first via layer V0 formed on the source/drain contacts formed on the source/drain of the transistor and the gate contacts formed on the gate electrode, patterns of the first interconnection layer M1 formed on top of the first via layer V0, vias of the second via layer V1 formed on top of the first interconnection layer M1, patterns of the second interconnection layer M2 formed on top of the second via layer V1, vias of the third via layer V2 formed on top of the second interconnection layer M2, and patterns of the third interconnection layer M3 formed on top of the third via layer V2. In some example implementations, the source/drain contacts and/or gate contacts may be connected to the patterns of the first interconnection layer M1 without going through the vias of the first via layer V0. Hereinafter, example implementations referring to FIG. 5 to FIG. 9 are described, without describing the common parts with the above-described contents.

Referring to FIG. 10 to FIG. 12, the first pattern M31 of the third interconnection layer M3 may be the first word line WL_A corresponding to the first port, or a pattern electrically connected to the first word line WL_A. The second pattern M32 of the third interconnection layer M3 may be the second word line WL_B corresponding to the second port, or a pattern electrically connected to the second word line WL_B. The first pattern M31 and the second pattern M32 of the third interconnection layer M3 may extend in the second direction and be spaced apart from each other in the first direction. The first pattern M31 of the third interconnection layer M3 may be electrically connected to the first pattern M11 of the first interconnection layer through the first pattern M21 of the second interconnection layer M2, and the second pattern M32 of the third interconnection layer M3 may be electrically connected to the first pattern M11 of the first interconnection layer through the second pattern M22 of the second interconnection layer M2. In some example implementations, a via of the third via layer V2 may be formed between the first pattern M31 of the third interconnection layer M3 and the first pattern M21 of the second interconnection layer M2, and between the second pattern M32 of the third interconnection layer M3 and the second pattern M22 of the second interconnection layer M2. A via of the second via layer V1 may be formed between the first pattern M21 of the second interconnection layer M2 and the first pattern M11 of the first interconnection layer M1, and between the second pattern M22 of the second interconnection layer M2 and the second pattern M12 of the first interconnection layer M1. The first pattern M11 and the second pattern M12 of the first interconnection layer may be electrically connected to the first via V01 and the second via V02 of the first via layer V0 described above in FIG. 6.

Referring to FIG. 10 to FIG. 12, the third pattern M33 of the third interconnection layer M3 may be configured to apply the negative supply voltage VSS to the pull-down transistor PD1 and the second pull-down transistor PD2, and a fourth pattern M34 of the third interconnection layer M3 may be configured to apply the negative supply voltage VSS to the third pull-down transistor PD3 and the fourth pull-down transistor PD4. The third pattern M33 and the fourth pattern M34 of the third interconnection layer M3 may be extended in the second direction, and may be spaced apart from each other in the first direction. The first pattern M31 and the second pattern M32 of the third interconnection layer M3 may be placed between the third pattern M33 and the fourth pattern M34 of the third interconnection layer M3.

In some example implementations, the third pattern M33 of the third interconnection layer M3 may be electrically connected to the third pattern M13 of the first interconnection layer M1 through the third pattern M23 of the second interconnection layer M2, and the fourth pattern M34 of the third interconnection layer M3 may be electrically connected to the fourth pattern M14 of the first interconnection layer M1 through the fourth pattern M24 of the second interconnection layer M2.

In some example implementations, a via of the third via layer V2 may be formed between the third pattern M33 of the third interconnection layer M3 and the third pattern M23 of the second interconnection layer M2, and between the fourth pattern M34 of the third interconnection layer M3 and the fourth pattern M24 of the second interconnection layer M2. A via of the second via layer V1 may be formed between the third pattern M23 of the second interconnection layer M2 and the third pattern M13 of the first interconnection layer M1, and between the fourth pattern M24 of the second interconnection layer M2 and the fourth pattern M14 of the first interconnection layer M1.

As described above, the third pattern M13 of the first interconnection layer M1 may be electrically connected to the first pull-down transistor PD1 and the second pull-down transistor PD2, and the fourth pattern M14 of the first interconnection layer M1 may be electrically connected to the third pull-down transistor PD3 and the fourth pull-down transistor PD4. In some example implementations, the third pattern M13 of the first interconnection layer M1 may include a first portion extending in the second direction from a region where a common source of the first pull-down transistor PD1 and the second pull-down transistor PD2 is formed, a second portion extending in the first direction from the first portion and a third portion extending in the second direction from the second portion. In some example implementations, the fourth pattern M14 of the first interconnection layer M1 may include a first portion extending in the second direction from a region where a common source of the third pull-down transistor PD3 and the fourth pull-down transistor PD4 is formed, a second portion extending in the first direction from the first portion and a third portion extending in the second direction from the second portion.

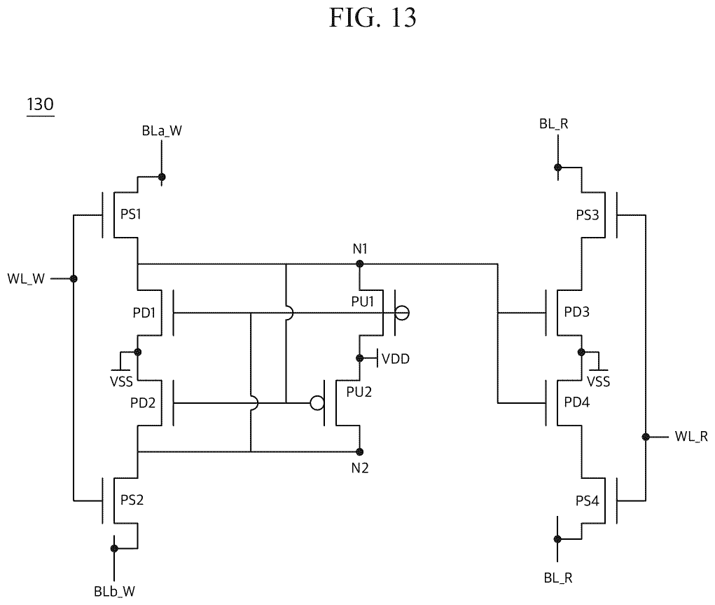

FIG. 13 is a circuit diagram illustrating a bit cell 130 according to some example implementations. The bit cell 130 of FIG. 13 may be an example of the bit line BC included in the integrated circuit 10 of FIG. 1, and as illustrated in FIG. 2, the bit cell 130 may be a 10T SRAM cell (or TP-SRAM cell) including 10 transistors. The explanation of the common parts with the above contents may be applied equally, and in the following, repetitive descriptions will be omitted.

Referring to FIG. 13, the bit cell 130 may include a plurality of pass transistors, a plurality of pull-down transistors and a plurality of pull-up transistors. The plurality of pass transistors may include the first pass transistor PS1 to the fourth pass transistor PS4, the plurality of pull-down transistors may include the first pull-down transistor PD1 to the fourth pull-down transistor PD4, and the plurality of pull-up transistors may include the first pull-up transistor PU1 and the second pull-up transistor PU2.

The first pass transistor PS1, the first pull-down transistor PD1, the second pull-down transistor PD2 and the second pass transistor PS2 may be connected in series between a first bit line BLa_W and a first complementary bit line BLb_W. The first pass transistor PS1 and the first pull-down transistor PD1 may be connected through the first data node N1, and the second pass transistor PS2 and the second pull-down transistor PD2 may be connected through the second data node N2. The negative supply voltage VSS may be applied to the node to which the first pull-down transistor PD1 and the second pull-down transistor PD2 are connected. The first pull-up transistor PU1 and the second pull-up transistor PU2 may be connected in series between the first data node N1 and the second data node N2. The positive supply voltage VDD may be applied to the node to which the first pull-up transistor PU1 and the second pull-up transistor PU2 are connected. The third pass transistor PS3, the third pull-down transistor PD3, the fourth pull-down transistor PD4 and the fourth pass transistor PS4 may be connected in series between the first connection node and the second connection node of a second bit line BL_R. The first connection node may be the node to which the second bit line BL_R and the third pass transistor PS3 are connected, and the second connection node may be the node to which the second bit line BL_R and the fourth pass transistor PS4 are connected. The negative supply voltage VSS may be applied to the node to which the third pull-down transistor PD3 and the fourth pull-down transistor PD4 are connected. The third pass transistor PS3 and the third pull-down transistor PD3 may be connected, and the fourth pass transistor PS4 and the fourth pull-down transistor PD4 may be connected.

The gates of the first pull-up transistor PU1 and the first pull-down transistor PD1 may be connected to each other, and be connected to the second data node N2. The gates of the second pull-up transistor PU2 and the second pull-down transistor PD2 may be connected to each other, and be connected to the first data node N1. In some example implementations, the gates of the third pull-down transistor PD3 and the fourth pull-down transistor PD4 may be connected to each other and to the first data node N1.

In some example implementations, the first pull-up transistor PU1 and the first pull-down transistor PD1 may be included in the first inverter, and the second pull-down transistor PD2 and the second pull-up transistor PU2 may be included in the second inverter. The first inverter and the second inverter may correspond to an inverter pair whose input and output are cross-coupled. In other words, an inverter pair may include a first inverter and a second inverter.

The first pass transistor PS1 may be electrically connected to the first bit line BLa_W corresponding to the first port (for example, the write port) through the first access node, and the second pass transistor PS2 may be electrically connected to the first complementary bit line BLb_W corresponding to the first port through the second access node. The first bit line BLa_W and the first complementary bit line BLb_W may correspond to a bit line pair. The third pass transistor PS3 may be electrically connected to the second bit line BL_R corresponding to the second port (for example, read port) through the third access node, and the fourth pass transistor PS4 may be electrically connected to the second bit line BL_R through the fourth access node. The gates of the first pass transistor PS1 and the second pass transistor PS2 may be electrically connected to a first word line WL_W corresponding to the first port, and the gates of the third pass transistor PS3 and the fourth pass transistor PS4 may be electrically connected to a second word line WL_R corresponding to the second port. In some example implementations, the bit cell 130 may only perform write operations through the first port, and may only perform read operations through the second port. For example, when the first pass transistor PS1 and the second pass transistor PS2 are turned on depending on the voltage applied through the first word line WL_W, the bit cell 130 may store data provided through the first bit line BLa_W and the first complementary bit line BLb_W. When the third pass transistor PS3 and the fourth pass transistor PS4 are turned on according to the voltage applied through the second word line WL_R, the bit cell 130 may output stored data through the second bit line BL_R.

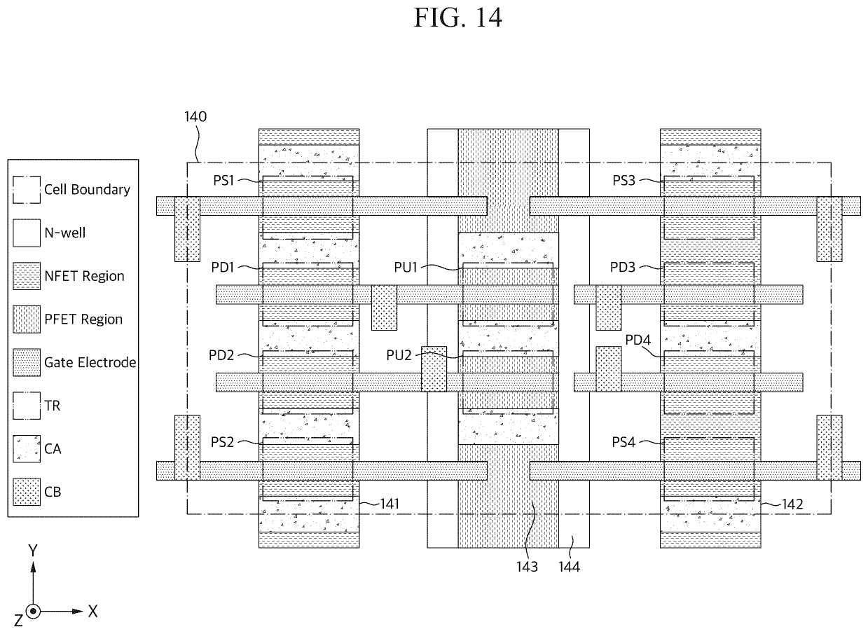

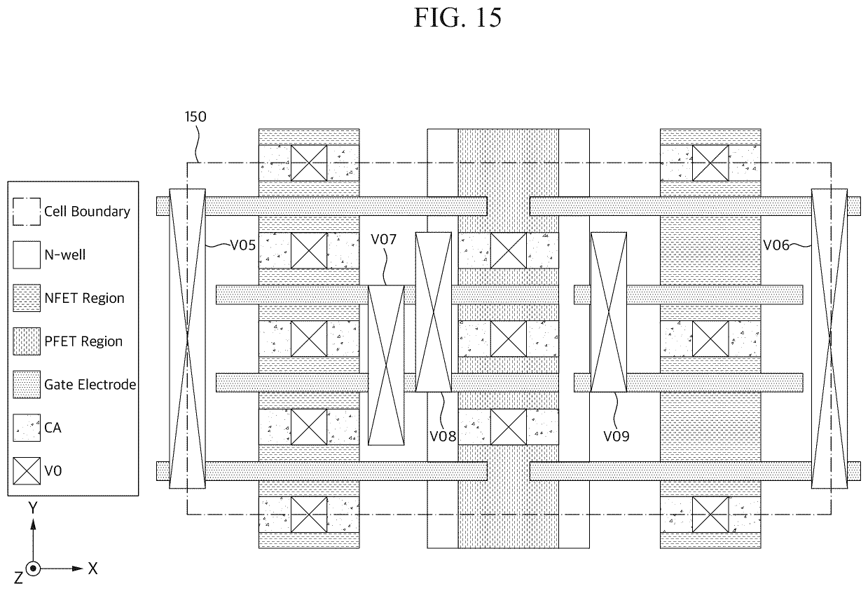

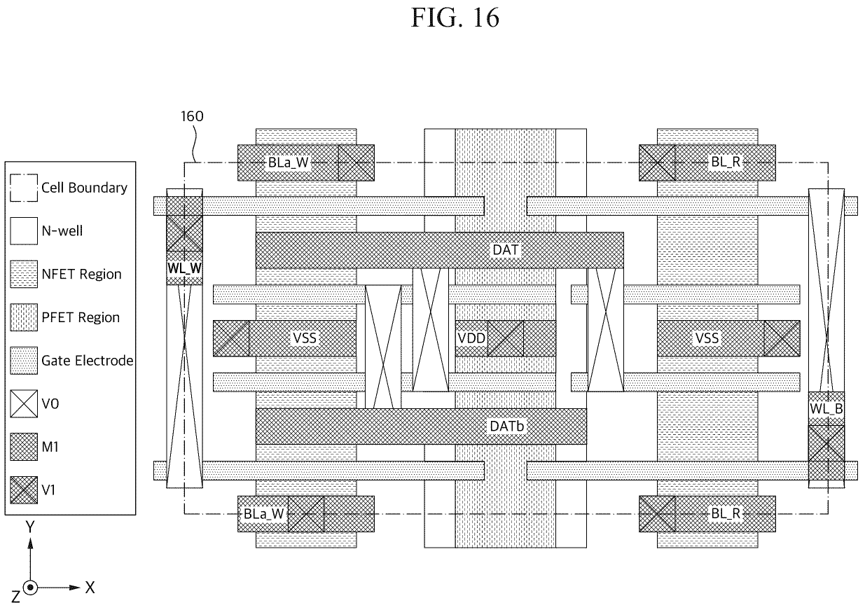

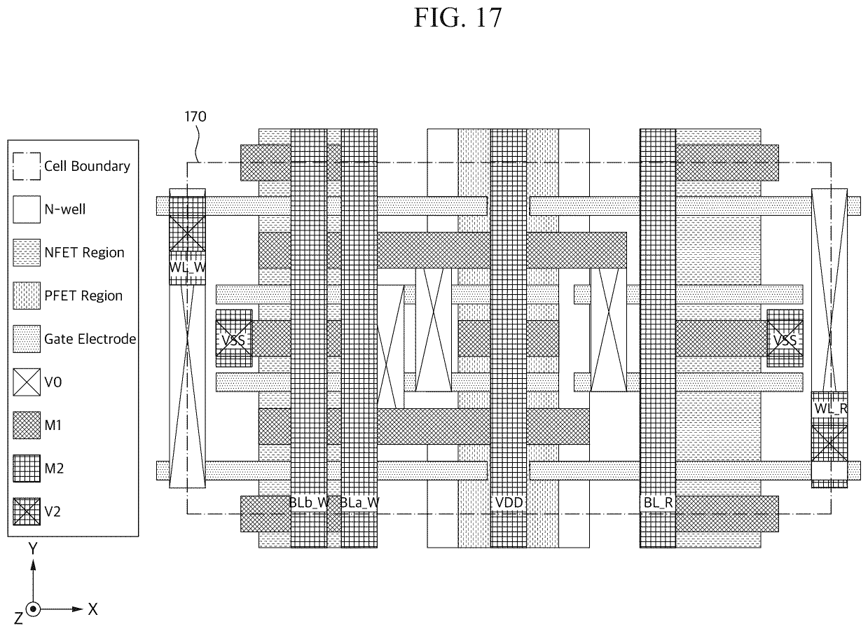

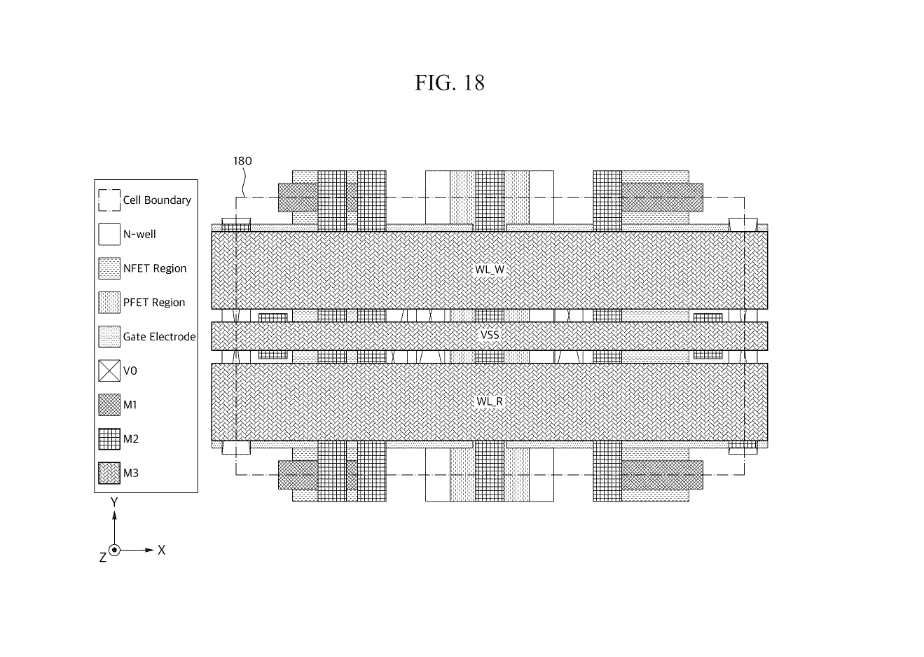

FIG. 14 to FIG. 18 are plan views illustrating the layout of bit cells according to some example implementations. For example, the plan views of FIG. 14 to FIG. 18 represent layouts corresponding to the bit cell 130 of FIG. 13. FIG. 14 illustrates a layout of a bit cell 140 where the source/drain contact CA and the gate contact CB are formed on the layout having the structures of the bit cell 40a and the bit cell 40b of FIG. 4A and FIG. 4B or an active pattern structure different therefrom. FIG. 15 illustrates the layout of a bit cell 150 in which the first via layer V0 is formed in the bit cell 140 of FIG. 14. FIG. 16 illustrates the layout of a bit cell 160 in which the first interconnection layer M1 and the second via layer V1 are formed in the bit cell 150 of FIG. 15. FIG. 17 illustrates the layout of a bit cell 170 in which the second interconnection layer M2 and the third via layer V2 are formed in the bit cell 160 of FIG. 16. FIG. 18 illustrates the layout of a bit cell 180 in which the third interconnection layer M3 is formed in the bit cell 170 of FIG. 17. The explanations in common with the above may be applied equally, and in the following, repetitive descriptions will be omitted.

Referring to FIG. 14 to FIG. 18, the bit cell 140, the bit cell 150, the bit cell 160, the bit cell 170 and the bit cell 180 may include a plurality of first transistors arranged in a first active region 141 extending in the first direction, a plurality of second transistors arranged in a second active region 142 extending in the first direction, and a plurality of third transistors arranged in a third active region 143 extending in the first direction. The second active region 142 may be spaced from the first active region 141 in the second direction. The third active region 143 may be placed between the first active region 141 and the second active region 142. In some example implementations, the bit cell 140, the bit cell 150, the bit cell 160, the bit cell 170 and the bit cell 180 may include a well region 144 extending in the first direction from the third active region 143. In some example implementations, the number of plurality of third transistors may be less than the number of plurality of first transistors. In some example implementations, the number of plurality of first transistors may be equal to the number of the plurality of second transistors.

In some example implementations, the bit cell 140, the bit cell 150, the bit cell 160, the bit cell 170 and the bit cell 180 may include at least one of contacts of the source/drain contact CA formed on top of the source/drain of the transistor, the gate contact CB contacts formed on top of the gate electrode, vias of the first via layer V0 formed on the source/drain contact CA and/or the gate contact CB, patterns of the first interconnection layer M1 formed on top of the first via layer V0, vias of the second via layer V1 formed on top of the first interconnection layer M1, patterns of the second interconnection layer M2 formed on top of the second via layer V1, vias of the third via layer V2 formed on top of the second interconnection layer M2, and patterns of the third interconnection layer M3 formed on top of the third via layer V2. In some example implementations, the source/drain contact CA and/or the gate contact CB may be connected to the pattern of the first interconnection layer M1 without going through the via of the first via layer V0. Following descriptions are written except for the common to the above with reference to FIG. 5 to FIG. 12.

Referring to FIG. 14 to FIG. 18, the first pull-down transistor PD1 among the plurality of first transistors and the first pull-up transistor PU1 among a plurality of third transistors may share a first gate electrode extending in the second direction. The second pull-down transistor PD2 among the plurality of first transistors and the second pull-up transistor PU2 among the plurality of third transistors may share a second gate electrode extending in the second direction.

In some example implementations, the first pass transistor PS1 may be connected between the first inverter and the first bit line BLa_W. For example, the first pass transistor PS1 may be connected to the drains of the first pull-down transistor PD1 and the first pull-up transistor PU1 included in the first inverter, and be connected to the pattern corresponding to the first bit line BLa_W. The second pass transistor PS2 may be connected between the second inverter and the first complementary bit line BLb_W. For example, the second pass transistor PS2 may be connected to the drains of the second pull-down transistor PD2 and the second pull-up transistor PU2 included in the second inverter, and be connected to the pattern corresponding to the first complementary bit line BLb_W. The third pass transistor PS3 may be connected between the third pull-down transistor PD3 and the second bit line BL_R, and the fourth pass transistor PS4 may be connected between the fourth pull-down transistor PD4 and the second bit line BL_R.

In some example implementations, the bit cell 140, the bit cell 150, the bit cell 160, the bit cell 170 and the bit cell 180 may include a first interconnection and a second interconnection. The first interconnection may be electrically connected to the drain of the first pull-down transistor PD1 and the first pull-up transistor PU1, and be electrically connected to the second gate electrode. In some example implementations, the first interconnection may include a pattern corresponding to an eighth via V08 of the first via layer V0 of FIG. 15 and the first data DAT of the first interconnection layer M1 of FIG. 16. The eighth via V08 of the first via layer V0 may be formed on the gate contact CB formed on the second gate electrode between the first active region 141 and the third active region 143, and be extended in the first direction. The eighth via V08 of the first via layer V0 may be electrically connected to the second gate electrode through the gate contact CB. The pattern corresponding to the first data DAT of the first interconnection layer M1 may be electrically connected to the drains of the first pull-down transistor PD1 and the first pull-up transistor PU1 through the first via layer V0 and the source/drain contact CA. The source/drain contacts may be formed on the drains of the first pull-down transistor PD1 and the first pull-up transistor PU1, and vias of the first via layer V0 may be formed on the source/drain contacts. The pattern corresponding to the first data DAT of the first interconnection layer M1 may be formed on the vias of the first via layer V0 and the eighth via V08, and be extended in the second direction. The pattern corresponding to the first data DAT of the first interconnection layer M1 may electrically connect the vias of the first via layer V0, which are electrically connected to the drains of the first pull-down transistor PD1 and the first pull-up transistor PU1, and the eighth via V08 of the first via layer V0.

In some example implementations, the first interconnection may be electrically connected to the gate electrode to each of the third pull-down transistor PD3 and the fourth pull-down transistor PD4. In some example implementations, the first interconnection may include a ninth via V09 of the first via layer V0 of FIG. 15. Contacts of the gate contact CB may be formed on the gate electrodes of the third pull-down transistor PD3 and the fourth pull-down transistor PD4, and the ninth via V09 of the first via layer V0 may be formed on top of the contacts of the gate contact CB. The ninth via V09 of the first via layer V0 may be extended in the first direction. Accordingly, the ninth via V09 of the first via layer V0 may be electrically connected to the contacts of the gate contact CB, which are electrically connected to the gate electrodes of the third pull-down transistor PD3 and the fourth pull-down transistor PD4, and may be electrically connected to a pattern corresponding to the first data DAT of the first interconnection layer M1.

The second interconnection may be electrically connected to the drains of the second pull-down transistor PD2 and the second pull-up transistor PU2, and may be electrically connected to the first gate electrode. In some example implementations, the second interconnection may include a pattern corresponding to a seventh via V07 of the first via layer V0 and second data DATb of the first interconnection layer M1. The same explanation as for the first interconnection may be applied to the second interconnection. With regard to the pattern corresponding to the seventh via V07 among the first via layer V0 and the second data DATb among the first interconnection layer M1, the description of the pattern corresponding to the eighth via V08 among the first via layer V0 and the first data DAT of the first interconnection layer M1 described above may be applied in a similar manner.

The second interconnection layer M2 may include a first pattern corresponding to the first bit line BLa_W, a second pattern corresponding to the first complementary bit line BLb_W, and a third pattern corresponding to the second bit line BL_R. The first bit line BLa_W and the first complementary bit line BLb_W may correspond to the bit line pair corresponding to the first port involved in the write operation, and the second bit line BL_R may correspond to the second port involved in the read operation. The first to third patterns of the second interconnection layer M2 may be extended in the first direction, and spaced apart from each other in the second direction. For example, the first pattern corresponding to the first bit line BLa_W of the second interconnection layer M2 may be electrically connected to the first pass transistor PS1 through the first pattern corresponding to the first bit line BLa_W of the first interconnection layer M1. In some example implementations, a first via of the second via layer V1 may be formed between the first pattern of the second interconnection layer M2 and the first pattern of the first interconnection layer M1. The second pattern corresponding to the first complementary bit line BLb_W of the second interconnection layer M2 may be electrically connected to the second pass transistor PS2 through the second pattern corresponding to the first complementary bit line BLb_W of the first interconnection layer M1. In some example implementations, a second via of the second via layer V1 may be formed between the second pattern of the second interconnection layer M2 and the second pattern of the first interconnection layer M1. The second via of the second via layer V1 may be formed spaced apart from the first via of the second via layer V1 in the second direction. Accordingly, the first pattern of the second interconnection layer M2 formed on the first via of the second via layer V1 and the second pattern formed on the second via of the second via layer V1 may be spaced apart from each other so as not to contact each other.

The third pattern corresponding to the second bit line BL_R of the second interconnection layer M2 may be electrically connected to the third pass transistor PS3 through the third pattern corresponding to the second bit line BL_R of the first interconnection layer M1. The third pattern corresponding to the second bit line BL_R of the first interconnection layer M1 may be formed on the area where the third pass transistor PS3 is formed, and a third via of the second via layer V1 may be formed between the third pattern corresponding to the second bit line BL_R of the second interconnection layer M2 and the third pattern corresponding to the second bit line BL_R of the first interconnection layer M1.

The fourth pattern corresponding to the second bit line BL_R of the second interconnection layer M2 may be electrically connected to the fourth pass transistor PS4 through the fourth pattern corresponding to the second bit line BL_R of the first interconnection layer M1. The fourth pattern corresponding to the second bit line BL_R of the first interconnection layer M1 may be formed on the area where the fourth pass transistor PS4 is formed, and a fourth via of the second via layer V1 may be formed between the fourth pattern corresponding to the second bit line BL_R of the second interconnection layer M2 and the fourth pattern corresponding to the second bit line BL_R of the first interconnection layer M1. The third via and the fourth via of the second via layer V1 may be formed at the same location in the second direction. Accordingly, the third pattern of the second interconnection layer M2 formed on the third via and the fourth via of the second via layer V1 may be formed as one pattern extending in the first direction.

The gate electrodes of the first pass transistor PS1 and the second pass transistor PS2 may be electrically connected to each other through a fifth via V05 of the first via layer V0, and the gate electrodes of the third pass transistor PS3 and the fourth pass transistor PS4 may be electrically connected to each other through a sixth via V06 of the first via layer V0. Since the above explanation may be applied equally to patterns corresponding to the first word line WL_W and the second word line WL_R, patterns corresponding to the negative supply voltage VSS and patterns corresponding to the positive supply voltage VDD, the repetitive descriptions are omitted.

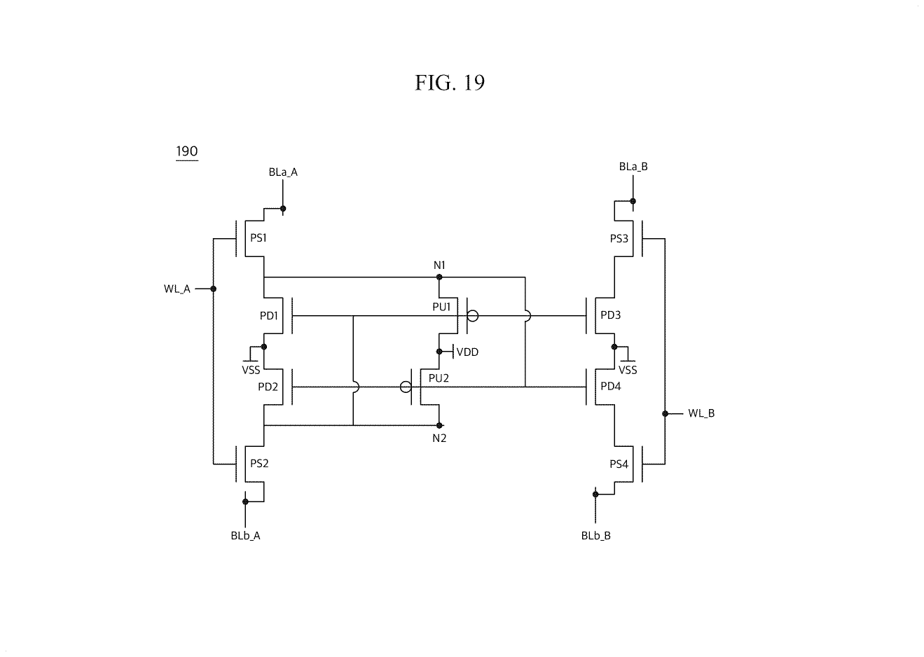

FIG. 19 is a circuit diagram illustrating a bit cell according to some example implementations. A bit cell 190 of FIG. 19 may be an example of the bit line BC included in the integrated circuit 10 of FIG. 1. As illustrated in FIG. 2, the bit cell 190 may be a 10T SRAM cell (or TP-SRAM cell) including 10 transistors. The explanations in common with the above may be applied equally, and repetitive descriptions will be omitted below.

Referring to FIG. 19, the bit cell 190 may include a plurality of pass transistors, a plurality of pull-down transistors, and a plurality of pull-up transistors. The plurality of pass transistors may include the first pass transistor PS1 to the fourth pass transistor PS4, the plurality of pull-down transistors may include the first pull-down transistor PD1 to the fourth pull-down transistor PD4, and the plurality of pull-up transistors may include the first pull-up transistor PU1 and the second pull-up transistor PU2.

In some example implementations, the bit cell 190 may selectively perform either a write operation or a read operation through the first word line WL_A corresponding to the first port. Alternatively, the bit cell 190 may perform a write operation through the first word line WL_A corresponding to the first port. The first pass transistor PS1, the first pull-down transistor PD1, the second pull-down transistor PD2 and the second pass transistor PS2 may be connected in series between the first bit line BLa_A and the first complementary bit line BLb_A. The first pull-up transistor PU1 and the second pull-up transistor PU2 may be connected in series between the first data node N1 and the second data node N2. The gates of the first pull-up transistor PU1 and the first pull-down transistor PD1 may be connected to each other, and be connected to the second data node N2. The gates of the second pull-up transistor PU2 and the second pull-down transistor PD2 may be connected to each other, and be connected to the first data node N1. The first pull-up transistor PU1 and the first pull-down transistor PD1 may be included in the first inverter, and the second pull-down transistor PD2 and the second pull-up transistor PU2 may be included in the second inverter. The first inverter and the second inverter may be included in an inverter pair whose inputs and outputs are cross-coupled. The gates of the first pass transistor PS1 and the second pass transistor PS2 may be connected to the first word line WL_A corresponding to the first port. When the first pass transistor PS1 and the second pass transistor PS2 are turned on due to the voltage applied to the gate through the activated first word line WL_A, the first pass transistor PS1 may connect the first bit line BLa_A and the first data node N1, and the second pass transistor PS2 may connect the first complementary bit line BLb_A and the second data node N2. For example, in the write operation, data (for example, bits and complementary bits) may be transferred from the first bit line BLa_A and the first complementary bit line BLb_A to the first data node N1 and the second data node N2. Further, in the read operation, data may be transmitted from the first data node N1 and the second data node N2 to the first bit line BLa_A and the first complementary bit line BLb_A.

In some example implementations, the bit cell 190 may perform a read operation through the second word line WL_B corresponding to the second port. The third pass transistor PS3, the third pull-down transistor PD3, the fourth pull-down transistor PD4 and the fourth pass transistor PS4 may be connected in series between the second bit line BLa_B and the second complementary bit line BLb_B. The gate of the third pull-down transistor PD3 may be connected to the gates of the first pull-up transistor PU1 and the first pull-down transistor PD1, and may be connected to the second data node N2. The gate of the fourth pull-down transistor PD4 may be connected to the gates of the second pull-up transistor PU2 and the second pull-down transistor PD2, and be connected to the first data node N1. The third pull-down transistor PD3 may not be connected to the first data node N1, and the fourth pull-down transistor PD4 may not be connected to the second data node N2. The gates of the third pass transistor PS3 and the fourth pass transistor PS4 may be connected to the second word line WL_B corresponding to the second port. When the third pass transistor PS3 and the fourth pass transistor PS4 are turned on due to the voltage applied to the gate through the activated second word line WL_B, the third pass transistor PS3 may connect the drains of the second bit line BLa_B and the third pull-down transistor PD3, and the fourth pass transistor PS4 may connect the drains of the second complementary bit line BLb_B and the fourth pull-down transistor PD4. According to some example implementations, by additionally placing two transistors, such as the third pull-down transistor PD3 and the fourth pull-down transistor PD4, the differential read may be operated, and accordingly, the bit cell 190 may perform read operations at improved speed. In the bit cell 190, the read operation may be performed independently through the third pull-down transistor PD3 and the fourth pull-down transistor PD4, without affecting (for example, disturbing) the data stored in the latch node. Accordingly, the bit cell 190 may reduce the disturbance phenomenon that may occur when operating with multiple ports.

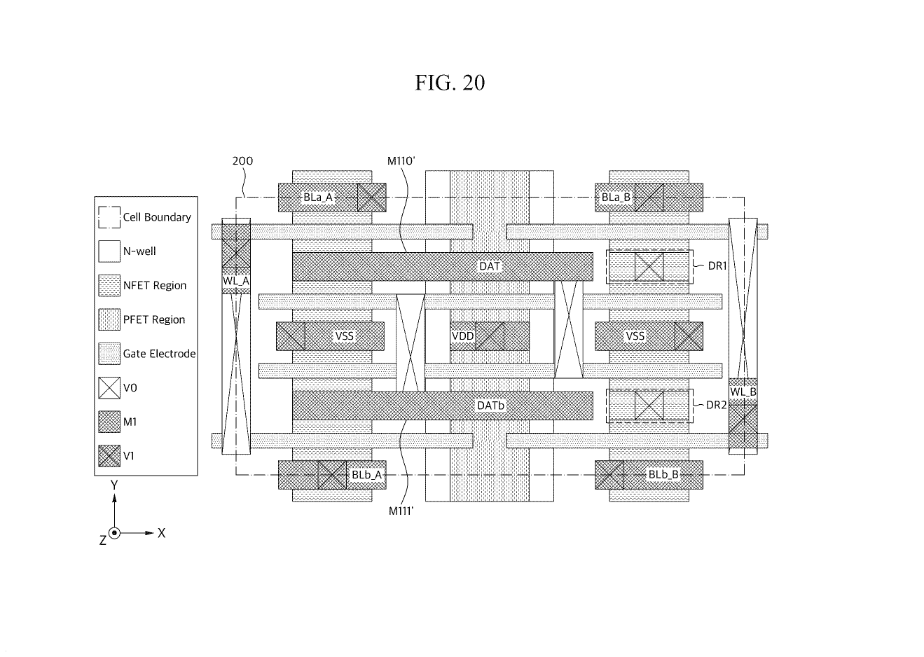

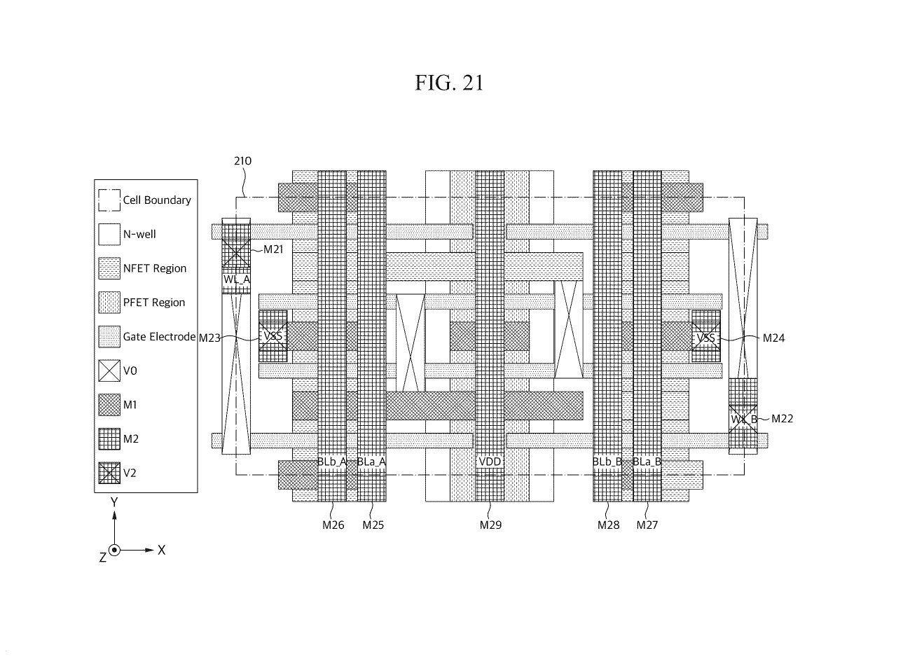

FIG. 20 and FIG. 21 are plan views illustrating the layout of a bit cell according to some example implementations. For example, the plan views of FIG. 20 and FIG. 21 represent layouts corresponding to the bit cell 190 of FIG. 19. FIG. 20 illustrates the layout of a bit cell 200 in which the tenth pattern M110 and the eleventh pattern M111 of the first interconnection layer M1 in the bit cell 70 of FIG. 7 are changed. FIG. 21 illustrates the layout of a bit cell 210 in which patterns of the second interconnection layer M2 and vias of the third via layer V2 are formed in the bit cell 200 of FIG. 20. Meanwhile, the bit cell 190 of FIG. 19 is not limited to the layouts of FIG. 20 and FIG. 21, and may be applied to example implementations of various layouts. With respect to parts that is common with the above descriptions, the above descriptions may be applied equally, and the repetitive descriptions are omitted below.

Referring to FIG. 20 and FIG. 21, the bit cell 200 and the bit cell 210 may include the first interconnection layer M1 and the second interconnection layer M2. The bit cell 200 and the bit cell 210 may further include the third interconnection layer M3 as illustrated in FIG. 9. The first interconnection layer M1 may include a tenth pattern M110′ and an eleventh pattern M111′. The tenth pattern M110′ and the eleventh pattern M111′ of FIG. 20 may be extended in the second direction, and the tenth pattern M110′ and the eleventh pattern M111′ may have shorter lengths in the second direction compared to the tenth pattern M110 and the eleventh pattern M111 illustrated in FIG. 7. In some example implementations, as illustrated in FIG. 20, the source/drain contacts and vias may be omitted in a first drain region DR1 of the third pull-down transistor PD3 and a second drain region DR2 of the fourth pull-down transistor PD4.

The tenth pattern M110′ of the first interconnection layer M1 may be electrically connected to the drains of the first pull-down transistor PD1 and the first pull-up transistor PU1. For example, referring to FIG. 5 and FIG. 6, the first source/drain contact CA1 and the seventh source/drain contact CA7 may be formed on the drains of the first pull-down transistor PD1 and the first pull-up transistor PU1. The first via layer V0 may be formed on top of the first source/drain contact CA1 and the seventh source/drain contact CA7. Referring to FIG. 20, over the vias of the first via layer V0 formed on the first source/drain contact CA1 and the seventh source/drain contact CA7, the tenth pattern M110′ of the first interconnection layer M1 may be extended in the second direction to be electrically connected to the first source/drain contact CA1 and the seventh source/drain contact CA7. The eleventh pattern M111′ of the first interconnection layer M1 may be electrically connected to the drains of the second pull-down transistor PD2 and the second pull-up transistor PU2. Since the description of the above-described tenth pattern M110′ may be equally applied to the eleventh pattern M111′, specific details are omitted.

The tenth pattern M110′ of the first interconnection layer M1 may be formed over the fourth via V04 of the first via layer V0 illustrated in FIG. 6, and may be electrically connected to the first gate electrode GE1 shared by the first pull-down transistor PD1, the first pull-up transistor PU1 and the third pull-down transistor PD3 illustrated in FIG. 5 through the fourth via V04 of the first via layer V0. The eleventh pattern M111′ of the first interconnection layer M1 may be formed on the third via V03 of the first via layer V0 illustrated in FIG. 6, and may be electrically connected to the second gate electrode GE2 shared by the second pull-down transistor PD2, the second pull-up transistor PU2 and the fourth pull-down transistor PD4 illustrated in FIG. 5 through the third via V03 of the first via layer V0.

The second interconnection layer M2 may include the first pattern M21 corresponding to the first word line WL_A, the second pattern M22 corresponding to the second word line WL_B, the third pattern M23 and the fourth pattern M24 corresponding to the negative supply voltage VSS, the fifth pattern M25 corresponding to the first bit line BLa_A, the sixth pattern M26 corresponding to the first complementary bit line BLb_A, the seventh pattern M27 corresponding to the second bit line BLa_B, the eighth pattern M28 corresponding to the second complementary bit line BLb_B, and the ninth pattern M29 corresponding to the positive supply voltage VDD. The fifth pattern M25 to the ninth pattern M29 of the second interconnection layer M2 may be extended in the first direction. The third interconnection layer M3 illustrated in FIG. 9 may include the first pattern M31 corresponding to the first word line WL_A, the second pattern M32 corresponding to the second word line WL_B and the third pattern M33 corresponding to the negative supply voltage VSS. The first pattern M31 to the third pattern M33 of the third interconnection layer M3 may be extended in the second direction. Since description on each pattern of the second interconnection layer M2 and the third interconnection layer M3 overlaps with the description above, the repetitive descriptions are omitted.

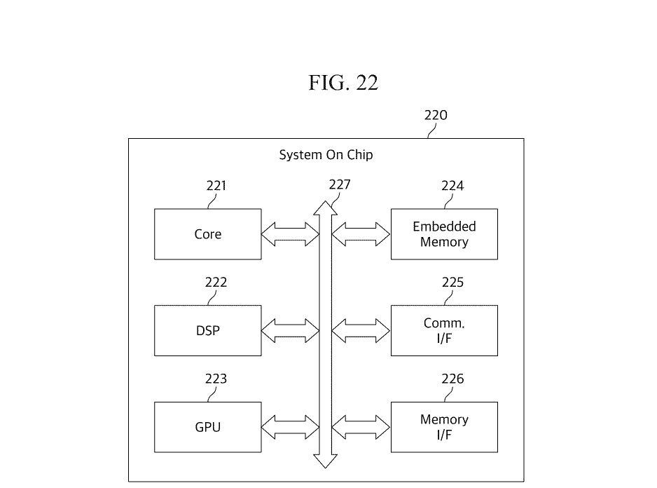

FIG. 22 is a block diagram illustrating a SoC according to some example implementations. For example, a SoC 220 may be used in a variety of applications including mobile devices, IoT devices, smart home appliances and automotive electronics systems, and the SoC 220 may adjust the configuration and performance of functional blocks to suit the needs of each application.

Referring to FIG. 22, the SoC 220 may include a core 221, DSP 222, GPU 223, embedded memory 224, a Comm. I/F 225, a Memory I/F 226, and a system bus 227 interconnecting them. The above-described integrated circuit 10 may be implemented in a form included in the core 221, the DSP 222, the GPU 223, the embedded memory 224, and the Comm. I/F 225.

The core 221 functions as the central processing unit of the SoC 220, executing instructions and controlling the overall operation of the SoC 220. The core 221 may have a single or multi-core architecture, and may be implemented based on various architectures such as ARM and x86.

The DSP 222 may process digital signals such as audio, video, and communication signals. The DSP 222 may perform operations such as filtering, transformation, and compression.

The GPU 223 may perform data processing related to visual information or artificial intelligence models, such as 2D and/or 3D graphics rendering, video encoding/decoding and so on. The GPU 223 has excellent parallel processing capabilities and may efficiently process data-intensive operations.

As a memory module integrated within the SoC 220, the embedded memory 224 may store data and instructions required by processors such as core 221. The embedded memory 224 may be implemented with various types of memory, such as SRAM, DRAM and flash memory. In some example implementations, the embedded memory 224 may include the bit cells described above with reference to the drawings. Accordingly, due to the high reliability and operating speed of the bit cell, reliability and performance of the embedded memory 224 and the SoC 220 may be improved.

The Comm. I/F 225 is an interface module that allows the SoC 220 to communicate with external devices. The Comm. I/F 225 may support various communication protocols such as USB, PCIe, UART, SPI, I2C, Ethernet and wireless communication (Wi-Fi and Bluetooth).

The Memory I/F 226 allows SoC 220 to communicate with external memory. The Memory I/F 226 may manage data exchange with external memory (for example, external DRAM, flash memory and so on).

The system bus 227 may interconnect components. Data, address and signals such as control signals may be transmitted via the system bus 227.

As described above, example implementations are disclosed with respect to the drawings in the present disclosure. In the present disclosure, the example implementations are described using specific terms, but the terms are used solely for the purpose of explaining the technical ideas of the present disclosure and are not intended to limit the meaning or scope of the present disclosure as set forth in the claims. Therefore, those skilled in the art will understand that various modifications and equivalent example implementations are possible based on this disclosure.

What is claimed is:

1. An integrated circuit comprising a plurality of bit cells,
wherein a first bit cell among the plurality of bit cells comprises:
a plurality of first transistors in a first active region extending in a first direction;
a plurality of second transistors in a second active region that is spaced apart from the first active region in a second direction intersecting the first direction, and that extends in the first direction; and
a plurality of third transistors in a third active region between the first active region and the second active region, wherein the third active region extends in the first direction, and wherein a number of the plurality of third transistors is smaller than a number of the plurality of first transistors.

2. The integrated circuit of claim 1, wherein the number of the plurality of first transistors is identical to a number of the plurality of second transistors.

3. The integrated circuit of claim 1, wherein the first bit cell comprises a well region extending from the third active region in the first direction.

4. The integrated circuit of claim 1, wherein the plurality of first transistors comprise a first pull-down transistor included in a first inverter and a second pull-down transistor included in a second inverter that is cross-coupled with the first inverter,
wherein the plurality of second transistors comprise a third pull-down transistor included in the first inverter and a fourth pull-down transistor included in the second inverter, and
wherein the plurality of third transistors comprise a first pull-up transistor included in the first inverter and a second pull-up transistor included in the second inverter.

5. The integrated circuit of claim 4, wherein the first pull-down transistor, the first pull-up transistor and the third pull-down transistor share a first gate electrode extending in the second direction, and
wherein the second pull-down transistor, the second pull-up transistor and the fourth pull-down transistor share a second gate electrode extending in the second direction.

6. The integrated circuit of claim 5, wherein the first bit cell comprises:
a first interconnection configured to connect drains of the first pull-down transistor, the first pull-up transistor, and the third pull-down transistor; and
a second interconnection configured to connect drains of the second pull-down transistor, the second pull-up transistor, and the fourth pull-down transistor.

7. The integrated circuit of claim 4, wherein the plurality of first transistors comprise a first pass transistor connected between the first inverter and a first bit line, and a second pass transistor connected between the second inverter and a first complementary bit line, and
wherein the plurality of second transistors comprise a third pass transistor connected between the first inverter and a second bit line, and a fourth pass transistor connected between the second inverter and a second complementary bit line.

8. The integrated circuit of claim 7, wherein the first bit cell comprises:
a first pattern electrically connected to a gate electrode of the first pass transistor and to a gate electrode of the second pass transistor, and that extends in the second direction; and
a second pattern electrically connected to a gate electrode of the third pass transistor and a gate electrode of the fourth pass transistor, and that extends in the second direction.

9. The integrated circuit of claim 8, wherein the first bit cell comprises a third pattern that is configured to receive a negative supply voltage, wherein the negative supply voltage is configured to be provided to the first pull-down transistor, the second pull-down transistor, the third pull-down transistor, and the fourth pull-down transistors, and wherein the third pattern extends in the second direction.

10. The integrated circuit of claim 7, wherein the first bit cell comprises:
a fourth pattern that is electrically connected to the first pass transistor, wherein the fourth pattern corresponds to the first bit line, and extends in the first direction;
a fifth pattern that is electrically connected to the second pass transistor, wherein the fifth pattern corresponds to the first complementary bit line, and extends in the first direction;
a sixth pattern that is electrically connected to the third pass transistor, wherein the sixth pattern corresponds to the second bit line, and extends in the first direction; and
a seventh pattern that is electrically connected to the fourth pass transistor, wherein the seventh pattern corresponds to the second complementary bit line, and extends in the first direction.

11. The integrated circuit of claim 10, wherein a first distance between the fourth pattern and the fifth pattern is shorter than a second distance between the fourth pattern and the sixth pattern, and
wherein a third distance between the sixth pattern and the seventh pattern is shorter than the second distance.

12. The integrated circuit of claim 1, wherein the plurality of first transistors comprise a first pull-down transistor included in a first inverter and a second pull-down transistor included in a second inverter that is cross-coupled with the first inverter,
wherein the plurality of second transistors comprise a third pull-down transistor and a fourth pull-down transistor, and
wherein the plurality of third transistors comprise a first pull-up transistor included in the first inverter and a second pull-up transistor included in the second inverter.

13. The integrated circuit of claim 12, wherein the first bit cell comprises:
a first interconnection that is connected to drains of the first pull-down transistor and the first pull-up transistor, and that is connected to the second gate electrode; and
a second interconnection that is connected to drains of the second pull-down transistor and the second pull-up transistor, and that is connected to the first gate electrode.

14. The integrated circuit of claim 13, wherein the first interconnection is connected to a gate electrode of each of the third pull-down transistor and the fourth pull-down transistor.

15. The integrated circuit of claim 13, wherein the plurality of first transistors comprise a first pass transistor connected between the first inverter and a first bit line, and a second pass transistor connected between the second inverter and a first complementary bit line, and
wherein the plurality of second transistors comprise a third pass transistor connected between the third pull-down transistor and a second bit line, and a fourth pass transistor connected between the fourth pull-down transistor and the second bit line.

16. The integrated circuit of claim 15, wherein the first bit cell comprises:
a first pattern that is electrically connected to the first pass transistor, wherein the first pattern corresponds to the first bit line, and extends in the first direction;
a second pattern that is electrically connected to the second pass transistor, wherein the second pattern corresponds to the first complementary bit line, and extends in the first direction; and
a third pattern that is electrically connected to the third pass transistor and the fourth pass transistor, wherein the third pattern extends in the first direction.

17. An integrated circuit comprising a plurality of bit cells,
wherein a first bit cell among the plurality of bit cells comprises:
a first pass transistor and a second pass transistor that are spaced apart from each other in a first direction, and that are connected to a first bit line and a first complementary bit line respectively;
a first pull-down transistor and a second pull-down transistor between the first pass transistor and the second pass transistor; and
a first pull-up transistor and a second pull-up transistor spaced apart from the first pull-down transistor and the second pull-down transistor respectively in a second direction that is intersecting the first direction.

18. The integrated circuit of claim 17, further comprising:
a third pass transistor and a fourth pass transistor that are spaced apart from each other in the first direction, and that are connected to a second bit line and a second complementary bit line respectively; and
a third pull-down transistor and a fourth pull-down transistor that are between the third pass transistor and the fourth pass transistor,
wherein the first pull-up transistor is between the first pull-down transistor and the third pull-down transistor, and
wherein the second pull-up transistor is between the second pull-down transistor and the fourth pull-down transistor.

19. The integrated circuit of claim 18, wherein the first bit cell comprises:
a first interconnection connecting drains of the first pull-down transistor, the first pull-up transistor, and the third pull-down transistor, and connecting gates of the second pull-down transistor, the second pull-up transistor, and the fourth pull-down transistor; and
a second interconnection connecting drains of the second pull-down transistor, the second pull-up transistor, and the fourth pull-down transistor, and connecting gates of the first pull-down transistor, the first pull-up transistor, and the third pull-down transistor.

20. An integrated circuit comprising a plurality of bit cells,
wherein a first bit cell among the plurality of bit cells comprises:
a first pattern extending in a first direction on a first interconnection layer, and configured to apply a positive supply voltage;
a second pattern extending in a second direction that is intersecting the first direction on a second interconnection layer, and configured to apply a negative supply voltage;
an inverter pair that is configured to be driven by the positive supply voltage and the negative supply voltage, and cross-coupled between a first data node and a second data node;
a first pass transistor connected to the first data node; and
a second pass transistor connected to the second data node, and spaced apart from the first pass transistor in the first direction,
wherein a first inverter of the inverter pair comprises a first pull-down transistor, a first pull-up transistor, and a second pull-down transistor that are in the second direction, and
wherein the first pull-down transistor is between the first pass transistor and the second pass transistor.
